(19) United States
(12) Patent Application Publication
(10) Pub. No.: US 2016/0260628 A1
(43) Pub. Date: Sep. 8, 2016

(54) DOOR OPENING AND CLOSING APPARATUS

(71) Applicant: SINFONIA TECHNOLOGY CO., LTD., Tokyo (JP)

(72) Inventor: Mitsutoshi Ochiai, Tokyo (JP)

(73) Assignee: SINFONIA TECHNOLOGY CO., LTD., Tokyo (JP)

(21) Appl. No.: 15/057,344

(22) Filed: Mar. 1, 2016

(30) Foreign Application Priority Data
Mar. 5, 2015 (JP) 2015-044780

(51) Int. Cl. H01L 21/677; E05F 15/73

(52) U.S. Cl. CPC H01L 21/67772; E05F 15/73; H01L 21/67766

(57) ABSTRACT

A door opening and closing apparatus shifts a door part holding a lid part of a storage container between a totally closed position where the inner space of the storage container body is sealed and a totally open position where the inner space of the storage container body is totally opened frontward, for putting in and taking out transfer target objects between the storage container and a transfer room. The door opening and closing apparatus puts the door part on standby at the predetermined halfway stop position every time a single access operation of a transfer robot to the storage container ends and until next access operation of the transfer robot to the storage container is performed.

### BACKGROUND OF THE INVENTION

(1) Field of the Invention

The present invention relates to a door opening and closing apparatus disposed adjacent to a transfer room. A storage container storing transfer target objects is placed on the door opening and closing apparatus. The door opening and closing apparatus opens and closes a door such that an inner space of the storage container is opened and closed for the transfer target objects to be put in and taken out between the transfer room and the storage container.

(2) Description of Related Art

For example, in a semiconductor manufacturing process, wafers are processed in a clean room for improving yields and quality. However, with today's highly integrated devices, miniaturized circuitry, and wafers of increased sizes, it has been becoming difficult to manage fine dust in the entire clean room, in terms of both costs and techniques. Therefore, in recent years, “the minienvironment system” is employed replacing the method for improving the cleanliness of the entire clean room. In the minienvironment system, the cleanliness of only a local space around wafers is improved, and processes of transferring wafers and others are performed.

In the minienvironment system, a door opening and closing apparatus (referred to as a load port) is provided adjacent to a transfer room. The door opening and closing apparatus structures part of the wall surface of a wafer transfer room which is substantially closed inside a case. On the door opening and closing apparatus, a storage container (e.g., a storage container called Front-Opening Unified Pod: FOUP) storing transfer target objects in a highly clean inner space is placed. The door opening and closing apparatus has a door part which opens and closes a lid part of the storage container while being closely attached to the lid part.

Such a door opening and closing apparatus is an apparatus for putting in and taking out wafers being transfer target objects to and from the transfer room, and functions as an interface part between the transfer room and the storage container. Then, when the door part of the door opening and closing apparatus and the lid part provided at the front surface of the storage container are simultaneously opened in the state where the door part is closely attached to the lid part, a transfer robot provided in the transfer room takes out the transfer target objects in the storage container to the transfer room, or stores the transfer target objects in the storage container through the door opening and closing apparatus from the transfer room.

The conventional door opening and closing apparatus is capable of putting the door part, which holds the lid part capable of closing the inner space opened frontward the storage container body, on standby at one of a totally closed position where the inner space of the storage container body is sealed by the lid part, and a totally open position where the inner space of the storage container is totally opened frontward. Then, the door part is put on standby at the totally open position from the start to the end of a process of putting in or taking out the transfer target objects to and from one storage container.

In recent years, integration and miniaturization of devices are highly increasingly pursued. It is demanded to maintain a higher level of cleanliness around the transfer target objects such as wafers, in order to avoid particles or moisture from attaching to the surface of the transfer target objects. Further, in order to prevent any changes, such as oxidation, at the surface of the transfer target objects, it is also practiced to place the transfer target objects in an atmosphere of nitrogen being an inert gas, or under vacuum.

In order to properly maintain an ambient atmosphere of the transfer target object, as disclosed in JP 2009-038074 A, there is also devised and brought into practical use a door opening and closing apparatus having a function of purging inside a sealable storage pod type storage container (e.g., the FOUP) with an environmental gas such as nitrogen or dry air.

However, with the above-described structure in which the door part is put on standby at the totally open position from the start to the end of a process of putting in or taking out the transfer target objects to and from one storage container, the purge concentration of the ambient atmosphere of the transfer target objects stored in the environmental gas atmosphere of a sufficient purge concentration in the storage container sealed by the lid part continuously reduces because of the door part kept on standby at the totally open position. As a result, the transfer target objects are exposed in the environment of the reduced purge effect for a long period. Hence, the quality reduces, and the full effect of the miniaturization may not be exhibited.

Accordingly, it may be contemplated to increase the purge amount of the environmental gas from the start to the end of a process of putting in or taking out the transfer target objects to and from the storage container, that is, while the door part is kept on standby at the totally open position. However, this is disadvantageous in an increase in costs and the use amount of the environmental gas necessary for the purge process.

Further, a mode may also be contemplated in which the door part is shifted from the totally open position to the totally closed position every time the transfer target object is put in or taken out to and from the storage container, thereby reducing the time period during which the door part is on standby at the totally open position, to suppress a reduction in the purge concentration of the environmental gas in the storage container. However, in this mode, the number of times of shifting the door part between the totally open position and the totally closed position increases. In accordance therewith, there is also an increase in the number of times of portions of the lid part and the storage container body, which would be closely attached to each other in the sealed state, being brought into contact with each other, and in the number of times of retainers that may be provided at the lid part and the transfer target object being brought into contact with each other. This invites disadvantageous effects such as generation of particles attributed to such contacts, and eventually a reduction in yields due to generation of such dust.

Note that, JP 2009-038074 A discloses the following processing method which makes it possible to suppress the partial pressure of an oxidizing gas such as oxygen in the storage container to a predetermined low level even after the inner space of the storage container is opened. That is, the door that attains a retract attitude (a tilted attitude), where the lid part is shifted into the transfer room, by being pivoted by a predetermined angle while holding the lid part, is shifted vertically downward while maintaining the retract attitude, and positioned at the retract position. Thus, the state where the inner space of the storage container is totally opened to the transfer room is entered. Then, every time the transfer target object is put in or taken out, the door in the retract attitude is raised from the retract position, and an airflow curtain flowing from an upper point toward a lower point on the transfer room side is caused to hit the lid part held by the door in the retract attitude (the tilted attitude). Thus, the flow of gas forming the airflow curtain is directed into the storage container.

With such a processing method, as compared to the case where the inner space of the storage container is totally opened until the process of putting in and taking out all the transfer target objects end, the airflow curtain can be used as the purge gas supply route to the inner space of the storage container, and therefore the purge efficiency can be improved. However, it is essential, for the processing method, that the airflow curtain is formed at a time point where the door in the retract attitude is raised from the retract position. and an increase in cost is disadvantageously invited in accordance with the use amount of gas for forming the airflow curtain in addition to the purge gas.

In the first place, the processing method is based on the technical idea in which: when the door is shifted downward while maintaining the retract attitude being the attitude of the door tilted by a predetermined angle, the door arrives at the retract position (a totally open position); the door is shifted vertically upward from the retract position; and the airflow curtain is caused to hit the lid part to direct the flow of gas into the storage container. That is, this is on condition that, at the time point where the door is set to the retract attitude, the entire lid part held by the door is present inside the transfer room. Accordingly, even when the door at the retract position (the totally open position) is raised while maintaining the retract attitude every time the transfer target object is put in or taken out to and from the storage container, the opening formed at the frame is not closed by the door at all. Therefore, unless the airflow curtain is formed, the gas atmosphere in the transfer room enters the storage container, causing a reduction in the purge concentration in the storage container.

The present invention has been made focusing on such problems, and a chief object thereof is to provide a door opening and closing apparatus capable of preventing or suppressing generation of dust by contact or the like between a lid part and a storage container body while a transfer target object is put in or taken out to and from a storage container, and maintaining and securing the purge concentration at a predetermined value or higher in the storage container, without using a large amount of an environmental gas.

### SUMMARY OF THE INVENTION

That is, the present invention relates to a door opening and closing apparatus including: a plate-like frame that structures part of a wall surface of a transfer room and is provided with an opening for opening the transfer room; a door part capable of opening and closing the opening; and a placing pedestal on which a storage container having a storage container body and a lid part capable of opening and closing an inner space of the storage container body can be placed such that the lid part faces the door part, wherein the door part opens and closes when a transfer target object is transferred by a transfer robot disposed in the transfer room between the storage container and the transfer room, the door part opening and closing while shifting between a totally closed position where the inner space of the storage container body is sealed at least by the lid part held by the door part and a totally open position where the inner space of the storage container body is totally opened frontward.

In the present invention, in the front-rear direction along which the storage container placed on the placing pedestal and the frame are aligned with each other, the frame side is defined to be the front side, and the storage container side is defined to be the rear side. Here, the transfer target object in the present invention may be a wafer, a reticle, a liquid crystal transfer target object, a glass transfer target object, a culture plate, a culture vessel, a dish, a petri dish and the like, and the present invention is applicable to the technique of transferring the transfer target object stored in a container in various fields such as semiconductors, liquid crystals, cell cultivations and the like. The transfer room in the present invention is a room for transferring the transfer target object. Accordingly, when the transfer target object is for example a wafer, the transfer room in the present invention is a wafer transfer room.

Further, the transfer robot is just required to be disposed in the transfer room, and any known transfer robot can be used. Note that, the transfer robot may or may not structure part of the door opening and closing apparatus of the present invention. A known transfer robot includes a linkage mechanism made up of a plurality of arm elements coupled to each other, and a hand provided at the tip of the linkage mechanism. With the hand, the transfer robot can grip the transfer target object to put in and take out the transfer target object between the storage container and the transfer room. However, the transfer robot in the present invention is not limited to this type.

Then, in the door opening and closing apparatus of the present invention, every time a single access operation or a series of access operations of the transfer robot to the storage container subjected to a purge process with an environmental gas ends and until immediately before next access operation of the transfer robot to the storage container is performed, the door part becomes on standby at a predetermined halfway stop position on the front side than the totally closed position and where a rearmost inner surface of the lid part is on the rear side than a frame foremost surface.

Here, the rearmost inner surface of the lid part is a surface being nearest to a back surface of the storage container body, in the inner surface facing the inner space of the storage container body, in the lid part. Further, the frame foremost surface is a surface being farthest from the storage container body at a circumference of the opening, in the frame.

The “storage container subjected to a purge process with an environmental gas” in the present invention includes both a storage container subjected to the purge process at any appropriate timing at and after the time point where the storage container is placed on the placing pedestal of the door opening and closing apparatus, and a storage container having previously undergone the purge process at the time point before being placed on the placing pedestal.

Specific examples of the timing at which the purge process is performed at and after the time point where the storage container is placed on the placing pedestal of the door opening and closing apparatus may be: the time point before the storage container is brought into contact with the frame; the time point before the lid part of the storage container is brought into contact with the door part; and the time point before the door part is shifted from the totally closed position to a predetermined position by the lid part. Note that, in the present invention, the purge process may be performed on the storage container at and after the time point where the sealed state of the inner space of the storage container body is released. By performing the purge process on the storage container also at and after the time point where the sealed state of the inner space of the storage container body is released, the inside of the storage container is maintained at the positive pressure than the inside of the transfer room. Thus, it becomes possible to prevent the atmosphere in the transfer room or the outside air from flowing into the storage container through the clearance between the storage container and the door opening and closing apparatus.

Specific examples of the timing at which the purge process is previously performed at the time point before the storage container is placed on the placing pedestal of the door opening and closing apparatus may be: the time point where the storage container is stored in a storage capable of storing a plurality of storage containers: the time point where the storage container is placed on a dedicated purge station other than the door opening and closing apparatus; and any appropriate time point during the manufacturing process in another transfer target object manufacturing apparatus or after the manufacture.

The maximum number of the transfer target objects that can be transferred between the storage container and the transfer room by ““a single” access operation of the transfer robot to the storage container” in the present invention is determined by the number of a transfer target object gripping part (for example, a hand) of the transfer robot. That is, when the transfer robot includes one transfer target object gripping part, the maximum number of the transfer target object that can be transferred by a single access operation is one. Further, when the transfer robot includes two transfer target object gripping parts, the maximum number of the transfer target object that can be transferred by a single access operation is two.

Further, the process of “transferring the transfer target object between the storage container and the transfer room” in the present invention includes the process of taking out the transfer target object from inside the storage container to the transfer room, and the process of putting in (storing) the transfer target object from inside the transfer room into the storage container. These processes can be regarded as the taking out process and the putting in process in terms of shifting operations of the transfer target object relative to the storage container.

In the door opening and closing apparatus of the present invention, every time a single access operation of the transfer robot to the storage container ends and until immediately before next access operation of the transfer robot to the storage container is performed, the door part becomes on standby at a predetermined halfway stop position on the front side than the totally closed position and where the rearmost inner surface of the lid part is on the rear side than the frame foremost surface. With such a structure, as compared to the structure in which the door part is kept on standby at the totally open position from the start of the transfer process of the transfer target objects in the storage container until the end of the transfer processes of all the transfer target objects, every time the access operation of the transfer robot to the storage container ends, the inner space of the storage container can be blocked in the front-rear direction by the lid part held by the door part on standby at the halfway stop position without allowing communication with the transfer room. Accordingly, the time period can be shortened during which the entire inner space of the storage container is totally opened to the transfer room until the transfer robot finishes the transfer processes of all the transfer target objects in the storage container. Thus, the purge concentration of the environmental gas in the inner space of the storage container can be prevented from continuously reducing. In the present invention, the halfway stop position of the door part can be arbitrarily set within a range satisfying the condition that the position is on the front side (on the frame side) than the totally closed position and where the rearmost inner surface of the lid part is on the rear side (on the storage container side) than the frame foremost surface. That is, the halfway stop position of the door part in the present invention can be arbitrarily set in a range from the position of the door part close to the totally closed position but not reaching the totally closed position, to the position of the door part where the rearmost inner surface of the lid part is on the rear side than the frame foremost surface.

Further, in order to shorten the time period during which the entire inner space of the storage container is totally opened to the transfer room, preferably the door part becomes on standby at a predetermined halfway stop position every time a single access operation of the transfer robot to the storage container ends and until immediately before next access operation of the transfer robot to the storage container is performed. However, also with the structure in which the door part becomes on standby at a predetermined halfway stop position every time a series of access operations of the transfer robot to the storage container ends and until immediately before next access operation of the transfer robot to the storage container is performed, as compared to the structure in which the door part is kept on standby at the totally open position from the start of the transfer process of the transfer target objects in the storage container until the end of the transfer processes of all the transfer target objects, the time period during which the entire inner space of the storage container is totally opened to the transfer room can be shortened. Note that, in the case where the door part becomes on standby at a predetermined halfway stop position every time a series of access operations of the transfer robot to the storage container ends and until immediately before next access operation of the transfer robot to the storage container is performed, it is on condition that the term “a series” in “every time a series of access operations of the transfer robot ends” refers to the number of access operations smaller than the access operations of the transfer robot required for completing all the transfer processes to the transfer target objects in the storage container.

Additionally, with the door opening and closing apparatus of the present invention, the rearmost inner surface of the lid part held by the door part put on standby at the halfway stop position is positioned at a position being near to the inner space of the storage container through the opening formed at the frame. Thus, it is possible to reduce the clearance in the front-rear direction between the respective portions of the storage container body and the lid part which would be closely attached to each other in the sealed state. In combination with the effect of the above-described structure (the structure in which the inner space of the storage container can be blocked in the front-rear direction by the lid part without allowing communication with the transfer room), the ambient atmosphere of the transfer target objects stored in the storage container can be maintained in a predetermined purge concentration state (for example, a low moisture-concentration state).

Further, it is possible to prevent or suppress problems that may arise in the case where the door part is shifted from the totally open position to the totally closed position every time a single access operation of the transfer robot to the storage container ends, that is, generation of dust associated with an increase in the number of times the lid part and the storage container body being brought into contact with each other.

As described above, with the door opening and closing apparatus of the present invention, the ambient atmosphere of the transfer target objects stored in the storage container can be maintained in a predetermined low moisture-concentration state, for example without employing the structure in which the airflow curtain formed on the transfer room side is caused to hit the lid part in the tilted attitude to direct the flow of the gas into the storage container. Then, with the door opening and closing apparatus of the present invention, the purge concentration in the storage container can be maintained and secured at a predetermined value or higher without using a large amount of purge-purpose gas (environmental gas), and generation of dust can be prevented or suppressed. Hence, the risk of a reduction in the quality of the transfer target objects can be avoided. The door opening and closing apparatus described in detail above may be referred to as “the first door opening and closing apparatus of the present invention” in the following description.

Further, a door opening and closing apparatus of the present invention includes: a plate-like frame that structures part of a wall surface of a transfer room and is provided with an opening for opening the transfer room; a door part capable of opening and closing the opening; and a placing pedestal on which a storage container having a storage container body and a lid part capable of opening and closing an inner space of the storage container body can be placed such that the lid part faces the door part, wherein the door part opens and closes when a transfer target object is transferred by a transfer robot disposed in the transfer room between the storage container and the transfer room, the door part opening and closing while shifting between a totally closed position where the inner space of the storage container body is sealed at least by the lid part held by the door part and a totally open position where the inner space of the storage container body is totally opened frontward, the door part maintaining an attitude thereof while shifting. Then, the door part of the present invention shifts frontward and rearward between the totally closed position and a foremost position in a predetermined shifting direction switching region, and shifts upward and downward between the totally open position and a rearmost position in the shifting direction switching region. Every time a single access operation or a series of access operations of the transfer robot to the storage container subjected to a purge process with an environmental gas ends and until immediately before next access operation of the transfer robot to the storage container is performed, the door part becomes on standby at a predetermined halfway stop position on the front side than the totally closed position and before the foremost position in the shifting direction switching region. In the following, for the sake of convenience, the door opening and closing apparatus of an aspect of the present invention is referred to as “the second door opening and closing apparatus of the present invention”.

The second door opening and closing apparatus of the present invention is different from the first door opening and closing apparatus of the present invention in the following points. That is, the second door opening and closing apparatus of the present invention satisfies both the first condition that the door part shifts between the totally closed position and the totally open position while maintaining its attitude, and the second condition that the door part shifts in the front-rear direction between the totally closed position and the foremost position in the predetermined shifting direction switching region (frontward-rearward shift), and further shifts in the height direction between the totally open position and the rearmost position in the shifting direction switching region (up-down shift). Further, in the second door opening and closing apparatus of the present invention, the halfway stop position where the door part becomes standby every time a single access operation or a series of access operations of the transfer robot to the storage container ends and until immediately before next access operation of the transfer robot to the storage container is performed is a predetermined position on the front side than the totally closed position and before the foremost position in the shifting direction switching region. Though the second door opening and closing apparatus of the present invention is different from the first door opening and closing apparatus of the present invention in these points, the rest of the structure is the same.

Here, the door part shifts between the totally closed position and the totally open position via the shifting direction switching region. Then, when the route of the door part frontward-rearward shifting and the route of the door part up-down shifting cross each other at one point, the shifting direction switching region can be represented by a point. In this case, “the rearmost position in the shifting direction switching region” and “the foremost position in the shifting direction switching region” become an identical position. On the other hand, the route of the door part frontward-rearward shifting and the route of the door part up-down shifting may be connected to each other via the shifting direction switching region that can be represented by a straight or curved line extending in the direction different from the extending direction of the shifting route of the door part from the totally closed position to the shifting direction switching region and the extending direction of the shifting route of the door part from the totally open position to the shifting direction switching region. In this case, “the foremost position in the shifting direction switching region” and “the rearmost position in the shifting direction switching region” are positions spaced apart from each other in the front-rear direction and the height direction. The door part positioned at the foremost position in the shifting direction switching region can be shifted rearward toward the totally closed position. Note that, shifting of the door part between the foremost position and the rearmost position in the shifting direction switching region includes not only frontward-rearward shifting but also up-down shifting. Further, the door part positioned at the rearmost position in the shifting direction switching region can be shifted downward toward the totally closed position. Note that, the shifting of the door part between the rearmost position and the foremost position in the shifting direction switching region includes not only up-down shifting but also frontward-rearward shifting. Thus, “the foremost position in the shifting direction switching region” is the starting position of the door part shifting downward from the shifting direction switching region to the totally closed position, and the ending position of the door part shifting frontward from the totally closed position to the shifting direction switching region. Further, “the rearmost position in the shifting direction switching region” is the starting position of the door part shifting downward from the shifting direction switching region to the totally open position, and the ending position of the door part shifting upward from the totally closed position to the shifting direction switching region.

Then, the door part satisfying the first condition of shifting between the totally closed position and the totally open position while maintaining its attitude is also in the same attitude at the foremost position in the shifting direction switching region as the attitude at the totally closed position or the attitude at the totally open position. That is, the door part shifts between the totally closed position and the totally open position via the shifting direction switching region without any rotation operation or tilting operation. The door part shifts between the totally closed position and the totally open position while holding the lid part of the storage container. Accordingly, it is designed such that the lid part does not interfere with the frame when the door part shifts between the totally closed position and the totally open position via the shifting direction switching region.

In the second door opening and closing apparatus of the present invention, the door part becomes on standby at the predetermined halfway stop position on the front side than the totally closed position and before the foremost position in the shifting direction switching region every time a single access operation or a series of access operations of the transfer robot to the storage container ends and until next access operation of the transfer robot to the storage container is performed. With this structure, as compared to the structure in which the door part is kept on standby at the totally open position from the start of the transfer process of the transfer target objects in the storage container until the end of the transfer processes of all the transfer target objects, every time a single access operation or a series access operations of the transfer robot to the storage container ends, the inner space of the storage container can be blocked in the front-rear direction by the lid part held by the door part put on standby at the halfway stop position.

In particular, by setting the halfway stop position to a position between the foremost position in the shifting direction switching region and the totally closed position and relatively near to the totally closed position, the inner space of the storage container can be blocked in the front-rear direction by the lid part held by the door part put on standby at the halfway stop position without causing the lid part to reach inside the transfer room. On the other hand, by setting the halfway stop position to the same position as the foremost position in the shifting direction switching region, the lid part held by the door part put on standby at the halfway stop position also reaches inside the transfer room. However, in this case also, the space with which the inner space of the storage container communicates can be blocked in the front-rear direction. Accordingly, it becomes possible to shorten the time period during which the entire inner space of the storage container is totally opened toward the transfer room without being blocked in the front-rear direction at all until the transfer processes of all the transfer target objects in the storage container by the transfer robot end. Then, with the second door opening and closing apparatus of the present invention also, the clearance in the front-rear direction between the respective portions of the storage container body and the lid part which would be closely attached to each other in the sealed state can be reduced. As a result, the purge concentration of the environmental gas in the inner space of the storage container can be prevented from continuously reducing, and the ambient atmosphere of the transfer target objects stored in the storage container can be maintained in a predetermined purge concentration state (for example, a low moisture-concentration state).

As described above, with the second door opening and closing apparatus of the present invention, similarly to the first door opening and closing apparatus of the present invention, for example without employing the structure in which the airflow curtain formed on the transfer room side is caused to hit the lid part in the tilted attitude to direct the flow of the gas into the storage container, the ambient atmosphere of the transfer target objects stored in the storage container can be maintained in a predetermined low moisture-concentration state. Then, with the second door opening and closing apparatus of the present invention, the purge concentration in the storage container can be maintained and secured at a predetermined value or higher without using a large amount of purge-purpose gas (environmental gas), and generation of dust can be prevented or suppressed. Hence, the risk of a reduction in the quality of the transfer target objects can be avoided.

In particular, with the second door opening and closing apparatus of the present invention, since the door part passing through the shifting direction switching region is set to the same attitude as in the totally closed position, even when the entire lid part held by the door part reaches inside the transfer room, the spaced apart dimension between the opening of the frame and the lid part in the transfer room is identical or substantially identical on both the upper end side and the lower end side of the lid part. On the other hand, with the structure in which the door part at the totally closed position is rotated whereby the lid part takes the tilted attitude in the transfer room, the spaced apart dimension between the opening of the frame and the lid part in the transfer room is largely different between the upper end side and the lower end side of the lid part. With the second door opening and closing apparatus of the present invention, even when the entire lid part held by the door part reaches inside the transfer room, by virtue of the difference in the structure, as compared to the structure in which the door part at the totally closed position is rotated whereby the lid part takes the tilted attitude in the transfer room, the clearance in the front-rear direction between respective portions of the storage container body and the lid part which would be closely attached to each other in a sealed state can be reduced.

With any of the first door opening and closing apparatus of the present invention and the second door opening and closing apparatus, for example, a predetermined position of the door part on the front side than the totally closed position and where the rearmost inner surface of the lid part is on the rear side than the frame rearmost surface, which is situated at the circumference of opening and nearest to the storage container body, of the frame may be set as the halfway stop position. In this case, when the door part is positioned at the halfway stop position, at least the rearmost inner surface of the lid part further approaches toward the storage container through the opening of the frame. Therefore, the clearance in the front-rear direction between the opening edge of the storage container body to which the lid part would be closely attached in the sealed state and the lid part held by the door part put on standby at the halfway stop position can be further reduced.

Further, with the first door opening and closing apparatus and the second door opening and closing apparatus of the present invention, a predetermined position of the door part on the front side than the totally closed position and where the rearmost inner surface of the lid part is on the rear side than the storage container body foremost surface of the storage container body nearest to the frame rearmost surface may be set as the halfway stop position. Here, focusing on the fact that, with the storage container, mostly, the boundary between the inner space and the ambient space (outer space) of the storage container body not sealed by the lid part is the storage container body foremost surface, the rearmost inner surface of the lid part being at the position on the rear side than the storage container body foremost surface is the state where at least the rearmost inner surface of the lid part is in the inner space of the storage container body. Accordingly, the clearance in the front-rear direction between the opening edge of the storage container body to which the lid part would be closely attached in the sealed state and the lid part held by the door part put on standby at the halfway stop position can be further reduced, and the ambient atmosphere of the transfer target object in the storage container can be maintained at an excellent low moisture-concentration state (purge state).

Still further, with the first door opening and closing apparatus and the second door opening and closing apparatus of the present invention, the halfway stop position may be a position where elasticity of a retainer does not act, the retainer being provided at the inner surface (back surface) of the lid part and capable of elastically holding the edge of the transfer target object in a state where the inner space of the storage container body is sealed, that is, where the door part is shifted to the totally closed position. In this manner, setting the position on the front side of the totally closed position and where elasticity of the retainer does not act as the halfway stop position is preferable because, in addition to the above-described operation and effect, the risk of generation of dust associated with an increase in the number of the retainer provided at the inner surface of the lid part and the transfer target object being brought into contact with each other can also be prevented or suppressed.

With the door opening and closing apparatus of the present invention, the door part may be put on standby at the totally open position during an access operation of the transfer robot to the storage container. In this case, since the possibility of the hands or the like of the transfer robot being brought into contact with the door part can be eliminated, the opening and closing precision of the door part may not be excessively rigorous.

On the other hand, with the door opening and closing apparatus of the present invention, it is also possible to structure to cause, during an access operation of the transfer robot to the storage container, the door part to be on standby at an intermediate open position where the inner space of the storage container body is opened in the height direction just by the amount necessary for the access operation of the transfer robot. With such a structure, as compared to the structure where the door part is caused to be on standby in the totally open position during an access operation of the transfer robot to the storage container, it becomes possible to reduce the opened region along the height direction of the inner space of the storage container body during an access operation of the transfer robot to the storage container. As a result, a reduction in the purge concentration in the inner space can be effectively suppressed. Further, by employing the structure of causing the door part to be on standby at the intermediate open position during an access operation of the transfer robot to the storage container, it becomes also possible to reduce the shift stroke of the door part shifting between the totally open position and the halfway stop position. Note that, the intermediate open position during the transfer process of a transfer target object stored in the lowermost stage in the storage container may become identical to or substantially identical to the totally open position.

In the present invention, in any of the structure in which the door part is put on standby at the totally open position during an access operation of the transfer robot to the storage container, and the structure in which the door part is put on standby at the intermediate open position during an access operation of the transfer robot to the storage container, the door part should be put on standby at the intermediate open position after the end of an access operation of the transfer robot to the storage container and until immediately before next access operation of the transfer robot to the storage container is performed. Here, the timing at which the door part is shifted from the totally open position or the intermediate open position to the halfway stop position is just required to be the timing at which the door part or the lid part and the transfer robot do not interfere with each other. That is, at the timing at which the door part or the lid part and the transfer robot do not interfere with each other, the door part may be shifted to the halfway stop position immediately after the end of an access operation of the transfer robot to the storage container. Further, in the case where the door part or the lid part and the transfer robot interfere with each other if the door part is shifted from the totally open position or the intermediate open position to the halfway stop position immediately after the end of an access operation of the transfer robot to the storage container, the door part should be shifted from the totally open position or the intermediate open position to the halfway stop position after a lapse of a predetermined time period from the time point immediately after the end of the access operation of the transfer robot to the storage container.

Note that, the door opening and closing apparatus of the present invention may include a controller (control unit) that exerts control by issuing instructions such as an instruction (signal) to shift the door part. In this case, the timing for shifting the door part from the totally open position or the intermediate open position to the halfway stop position may be the time point where the door opening and closing apparatus receives a door closing instruction. Further, the door opening and closing apparatus of the present invention may actuate upon receipt of instructions such as an instruction (signal) to shift the door part from a higher-level controller provided at the transfer apparatus, the processing apparatus, or the manufacturing apparatus, that is, the door opening and closing apparatus may not include any controller for controlling the actuation or the like of the door part. In this case, the timing at which the door part is shifted from the totally open position or the intermediate open position to the halfway stop position may be the time point where a higher-level controller issues a door closing instruction.

### Effect of the Invention

The present invention employs the novel technical idea in which, the door part is put on standby at the predetermined halfway stop position on the front side than the totally closed position and where the rearmost inner surface of the lid part is on the rear side than the frame foremost surface, or at the predetermined halfway stop position on the front side than the totally closed position and before the foremost position in the shifting direction switching region, every time a single access operation or a series of access operations of the transfer robot to the storage container subjected to a purge process with an environmental gas ends and until immediately before next access operation of the transfer robot to the storage container is performed. According to the present invention based on such a technical idea, the door opening and closing apparatus can be provided, with which generation of dust associated with an increase in the number of times the lid part and the storage container body being brought into contact with each other during the transfer process of the transfer target object to the storage container can be prevented or suppressed, and the purge concentration in the storage container can be prevented from reducing to a predetermined value or lower without using a large amount of environmental gas.

### BRIEF DESCRIPTION OF THE DRAWINGS

FIG. 1 is a side view schematically showing the relative positional relationship between an EFEM including a door opening and closing apparatus according to one embodiment of the present invention and its peripheral apparatuses:

FIG. 2 is a perspective view of the door opening and closing apparatus according to the embodiment:

FIG. 3 is a view on arrow x in FIG. 2;

FIG. 4 is a view on arrow y in FIG. 2;

FIG. 5 is a schematic cross-sectional view of the door opening and closing apparatus according to the embodiment as seen from the side, in the state where a storage container on a placing pedestal is spaced apart from a frame and a door part is at a totally closed position:

FIG. 6 is a diagram showing the state where the storage container on the placing pedestal is closely attached to the frame and the door part is at the totally closed position, in a manner corresponding to FIG. 5;

FIG. 7 is a diagram showing the state where the door part is at a shifting direction switching position, in a manner corresponding to FIG. 5;

FIG. 8 is a diagram showing the state where the door part is at a totally open position, in a manner corresponding to FIG. 5:

FIG. 9 is a schematic cross-sectional view of the door opening and closing apparatus according to the embodiment as seen from above at a predetermined height position in the state where the storage container on the placing pedestal is closely attached to the frame and the door part is at the totally closed position;

FIG. 10 is a diagram showing the state where the door part is at the totally open position, in a manner corresponding to FIG. 9;

FIG. 11 is a diagram showing the state where the door part is at a halfway stop position, in a manner corresponding to FIG. 9;

FIG. 12 is a diagram showing the state where the door part is at the totally closed position, in a manner corresponding to FIG. 9;

FIG. 13 is a flowchart showing the operation procedure of the EFEM according to the present embodiment;

FIG. 14 is a flowchart showing the operation procedure of the EFEM according to the present embodiment;

FIG. 15 is a diagram showing changes over time in the moisture concentration in the storage container:

FIG. 16 is a diagram showing changes over time in the moisture concentration in the storage container placed on the placing pedestal of the door opening and closing apparatus according to the present embodiment, in a manner corresponding to FIG. 15;

FIG. 17 shows one variation of the door opening and closing apparatus according to the embodiment, in a manner corresponding to FIG. 8;

FIG. 18 is a diagram showing changes over time in the moisture concentration in the storage container placed on the placing pedestal of the door opening and closing apparatus according to the variation, in a manner corresponding to FIG. 16;

FIG. 19 shows another variation of the door opening and closing apparatus according to the embodiment, in a manner corresponding to FIG. 4;

FIG. 20 is a partial enlarged view of the door opening and closing apparatus according to the variation as seen from a predetermined angle;

FIG. 21 is a plan view of the door opening and closing apparatus according to the variation, from which components are partially omitted;

FIG. 22 is a side view showing the door opening and closing apparatus according to the variation, from which components are partially omitted;

FIG. 23 is a schematic diagram showing the change in the attitude of a mapping unit in the variation, in a manner corresponding to FIG. 22;

FIG. 24 shows still another variation of the door opening and closing apparatus according to the embodiment, in a manner corresponding to FIG. 7; and

FIG. 25 is a diagram showing the variation, in a manner corresponding to FIG. 8.

### DETAILED DESCRIPTION OF PREFERRED EMBODIMENTS

In the following, with reference to the drawings, a description will be given of one embodiment of the present invention.

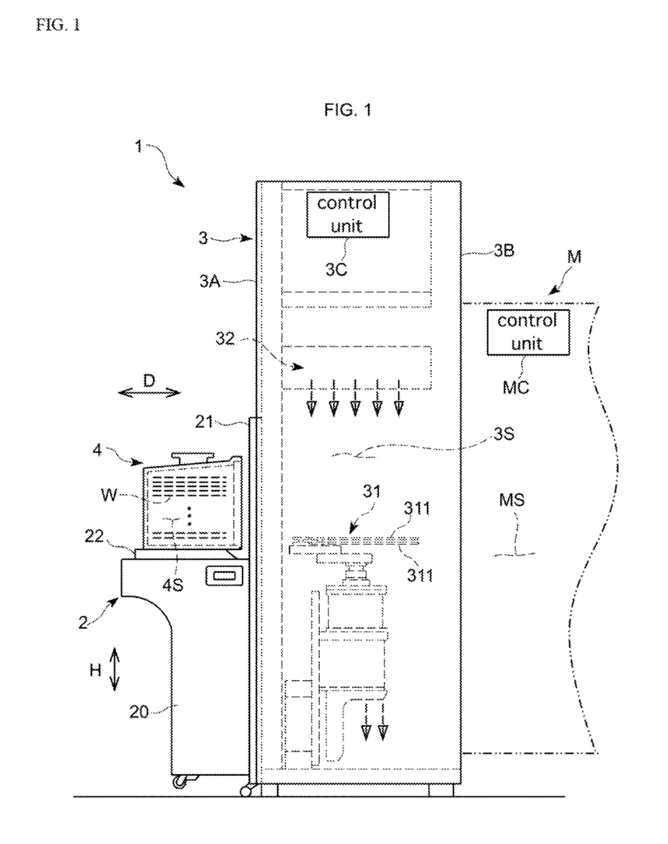

A door opening and closing apparatus 2 according to the present embodiment is used, for example, in a process of manufacturing semiconductors. As shown in FIG. 1, in a clean room, the door opening and closing apparatus 2 structures part of the wall surface of a transfer room 3, and puts in and takes out transfer target objects W between the transfer room 3 and a storage container 4. In the following, a description will be given of a mode in which the door opening and closing apparatus 2 is a load port that structures part of an EFEM (Equipment Front End Module) 1 being the transfer apparatus, and the transfer target objects W, for example wafers, are transferred between the storage container 4 (e.g., a FOUP) and the transfer room 3 (a wafer transfer room). Note that, while the size of wafers handled with the EFEM is standardized as SEMI (Semiconductor Equipment and Materials International) standards, from the viewpoint of improving productivity, the diameter of wafers has been increased. It is promoted to switch the wafer size from the conventional 300 mm diameter (a 150 mm radius) to the size ranging from a 450 mm diameter (a 225 mm radius) to a 500 mm diameter (a 250 mm radius).

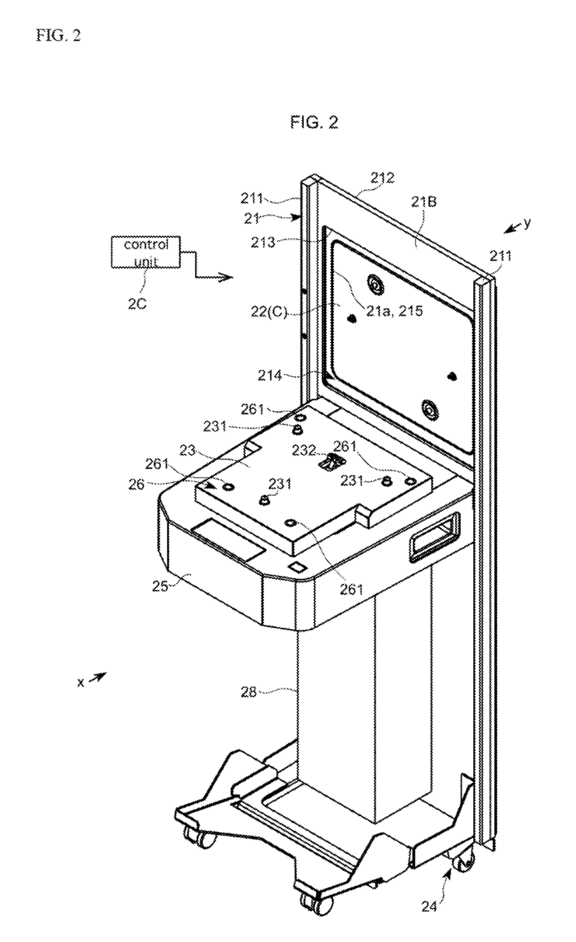

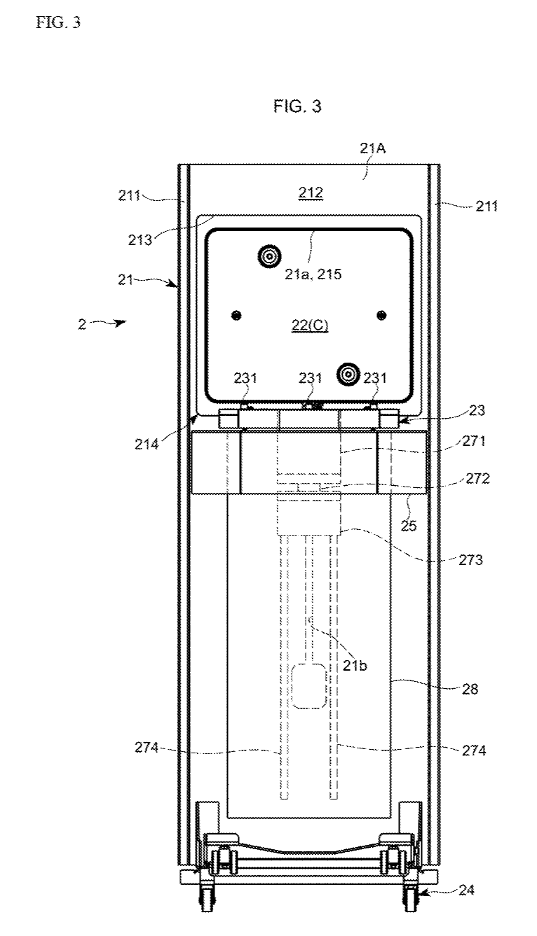

As shown in FIGS. 1 to 4, the door opening and closing apparatus 2 according to the present embodiment includes: a plate-shaped frame 21 that structures part of a wall surface of the transfer room 3, and is provided with an opening 21a for opening an inner space 3S of the transfer room 3; a door part 22 for opening and closing the opening 21a of the frame 21; and a placing pedestal 23 provided substantially horizontally to the frame 21. Further, FIGS. 2 and 3 show the state where an exterior cover 20 shown in FIG. 1 provided below the placing pedestal 23 is removed and the internal structure is partially exposed.

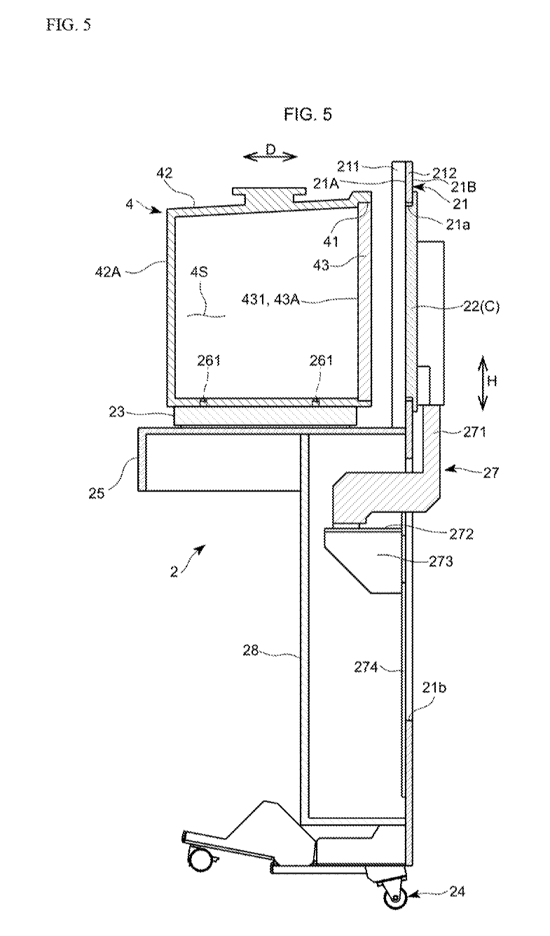

The frame 21 is disposed upright, and has an approximate quadrangular plate-shape. The frame 21 is provided with the opening 21a of the size communicable with a transfer opening 41 of the storage container 4 placed on the placing pedestal 23. The door opening and closing apparatus 2 according to the present embodiment can be used with the frame 21 closely attached to the transfer room 3. Further, below the frame 21, leg parts 24 having casters and installation legs are provided. In the present embodiment, the frame 21 includes support struts 211 stood on the opposite sides, a frame body 212 supported by the support struts 211, and a window unit 214 attached to a window part 213 opened to have an approximate quadrangular-shape at the frame body 212. The window unit 214 is provided facing a lid part 43 of the storage container 4. An opening 215 provided at the window unit 214 corresponds to the opening 21a formed at the frame 21 of the present invention. In FIG. 5 and subsequent drawings which will be referred to later, the window unit 214 is not shown. Instead, the frame 21 is schematically shown to have the frame body 212 provided with the opening 21a.

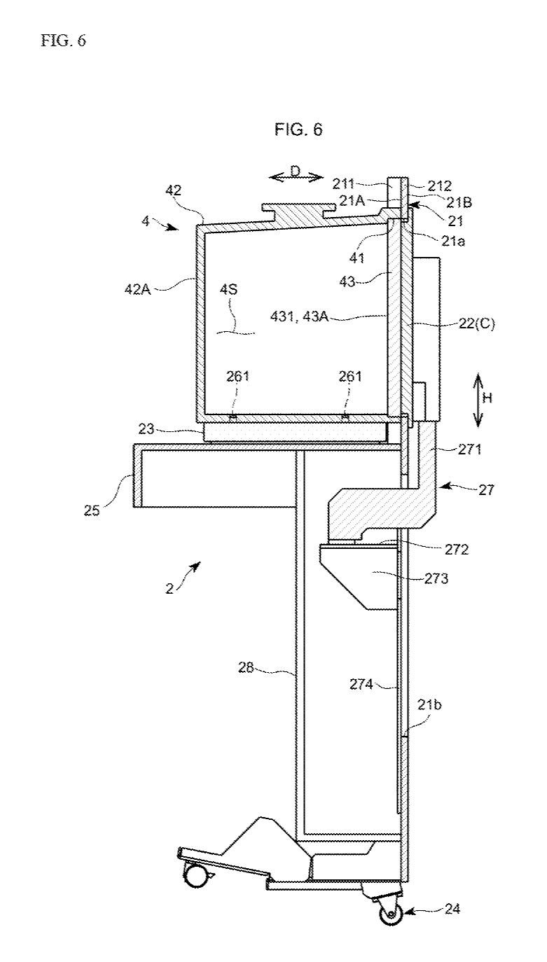

The placing pedestal 23 of the door opening and closing apparatus 2 is disposed at the upper portion of a horizontal pedestal 25 (a support pedestal) which is disposed substantially horizontally at the position slightly upper than the center in the height direction of the frame 21. On the placing pedestal 23, the storage container 4 can be placed such that the lid part 43 capable of opening and closing an inner space 4S of a storage container body 42 faces the door part 22. Further, the placing pedestal 23 is structured to be capable of approaching and retracting relative to the frame 21, between the position where the lid part 43 of the storage container 4 is closely attached to the door part 22 (see FIG. 6) and the position where the lid part 43 is spaced apart by a predetermined distance from the door part 22 (see FIG. 5). As shown in FIG. 2, the placing pedestal 23 has a plurality of projections 231 projecting upward. By allowing the projections 231 to engage with holes (not shown) formed at the bottom surface of the storage container 4, the storage container 4 is positioned on the placing pedestal 23.

Note that, in FIGS. 5 and 6 and others, as the placement state of the storage container 4 on the placing pedestal 23, the state where the bottom surface of the storage container 4 is in contact with the upper surface of the placing pedestal 23 is shown. However, actually, the storage container 4 is supported by the plurality of positioning projections 231 projecting higher than the upper surface of the placing pedestal 23 engaging with the bottomed holes formed at the bottom surface of the storage container 4. Accordingly, the upper surface of the placing pedestal 23 and the bottom surface of the storage container 4 are not in contact with each other, and a predetermined clearance is formed between the upper surface of the placing pedestal 23 and the bottom surface of the storage container 4.

Further, the placing pedestal 23 is provided with a lock claw 232 for fixing the storage container 4 to the placing pedestal 23. By attaining the locked state where the lock claw 232 is hooked and fixed to a lock receiving part (not shown) provided at the bottom surface of the storage container 4, in cooperation with the positioning projections 231, it becomes possible to guide the storage container 4 to a proper position on the placing pedestal 23 and fix the storage container 4 thereto. Further, by canceling the locked state of the lock claw 232 relative to the lock receiving part provided at the bottom surface of the storage container 4, the storage container 4 can be spaced apart from the placing pedestal 23.

In the present invention and the present embodiment, in the front-rear direction D (see FIG. 1 and others) along which the storage container 4 placed on the placing pedestal 23 of the load port and the frame 21 are aligned with each other, the frame 21 side is defined to be the front side, and the storage container 4 side is defined to be the rear side.

The door opening and closing apparatus 2 according to the present embodiment includes a bottom purge part 26 provided on the placing pedestal 23. The bottom purge part 26 is capable of injecting an environmental gas (also referred to as the purge gas, and mainly nitrogen gas or dry air is employed in the present embodiment), which is a gas appropriately selected from nitrogen gas, an inert gas, dry air and the like, from the bottom surface side of the storage container 4 into the storage container 4, thereby replacing the gas atmosphere in the storage container 4 by the environmental gas.

The bottom purge part 26 mainly includes a plurality of nozzles 261 provided at predetermined positions on the placing pedestal 23. The plurality of nozzles 261 are caused to function as a bottom purge injection nozzle for injecting a predetermined environmental gas, or a bottom purge discharge nozzle for discharging the gas atmosphere in the storage container 4. The plurality of nozzles 261 may be provided, for example, at the positions spaced apart in the width direction of the placing pedestal 23 as being paired. Further, the nozzles 261 can be fitted in and coupled to an injection port and a discharge port (both not shown) provided at the bottom part of the storage container 4. The nozzles 261 (the bottom purge injection nozzle, the bottom purge discharge nozzle) or the injection port and the discharge port have the valve function of preventing backflow of gas. The fitting portions between the nozzles 261 (the bottom purge injection nozzle, the bottom purge discharge nozzle) and the injection port and the discharge port of the storage container 4 are sealed by gaskets or the like provided at the tip portions of the nozzles 261. Note that, with the door opening and closing apparatus 2 according to the present embodiment, when the storage container 4 is not placed on the placing pedestal 23, the nozzles 261 (the bottom purge injection nozzle, the bottom purge discharge nozzle) are positioned lower than the upper surface of the placing pedestal 23. Then, for example when it is detected that a pressed part of a pressure sensor provided at the placing pedestal 23 is pressed by the bottom surface part of the storage container 4, the nozzles 261 (the bottom purge injection nozzle, the bottom purge discharge nozzle) are advanced upward by a signal from a control unit 2C, to couple to the injection port and the discharge port of the storage container 4. Thus, the state where a purge process can be performed is entered. By supplying an environmental gas into the inner space 4S of the storage container 4 from the bottom purge injection nozzle 261 via the injection port, and discharging the gas atmosphere (this gas atmosphere is air or an environmental gas of low cleanliness other than air, for a predetermined time period from the beginning of the execution of the purge process, and after a lapse of the predetermined time period, it is the environmental gas of high cleanliness with which the inner space 4S of the storage container 4 is filled) in the inner space 4S of the storage container 4 from the bottom purge discharge nozzle 261 via the discharge port, the purge process can be performed. Further, by setting the environmental gas supply amount to the inner space 4S of the storage container 4 to be greater than the discharge amount of the gas atmosphere of the inner space 4S of the storage container 4, the pressure of the inner space 4S of the storage container 4 can attain positive pressure, i.e., to be higher than the pressure of the inner space 3S of the transfer room 3 or outside. By maintaining the inner space 4S of the storage container 4 at positive pressure, the atmosphere in the transfer room 3 or outside air can be prevented from flowing into the storage container 4 from the clearance between the storage container 4 and the door opening and closing apparatus 2.

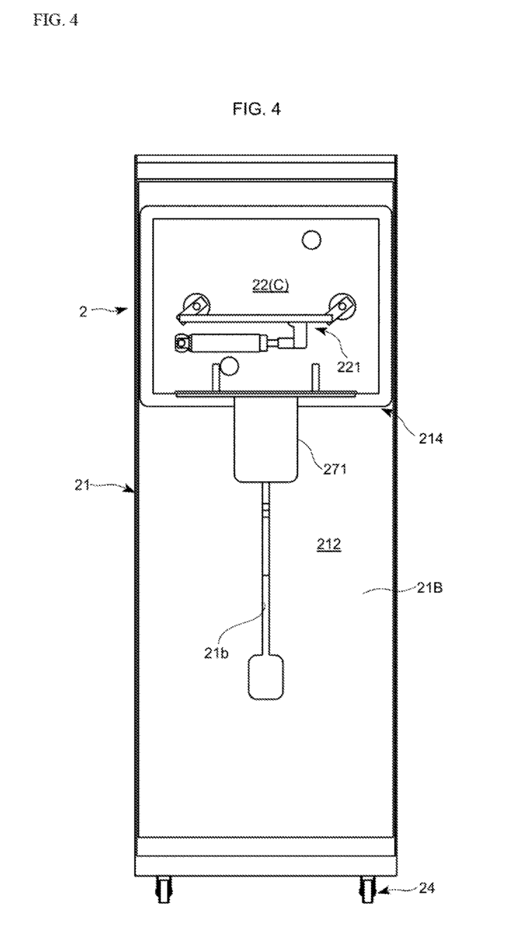

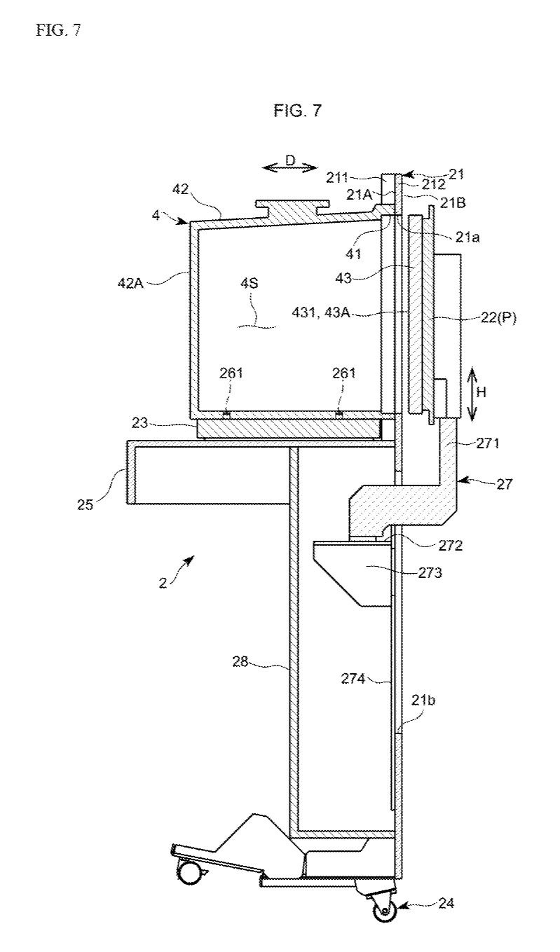

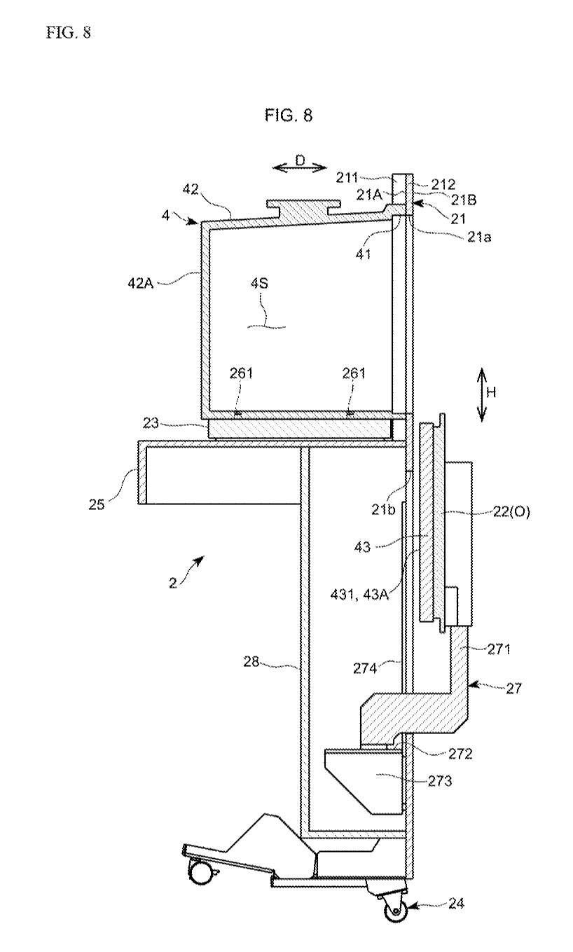

The door part 22 includes a coupling mechanism 221 (see FIG. 4) that is capable of switching between the lid coupled state in which the door part 22 is coupled to the lid part 43 of the storage container 4 and the lid part 43 can be removed from the storage container body 42, and the lid coupling released state in which the coupling state with the lid part 43 is released and the lid part 43 is attached to the storage container body 42. The door part 22 is capable of shifting along a predetermined shifting route while integrally holding the lid part 43 by the coupling mechanism 221. As shown in FIGS. 5 to 8, the door opening and closing apparatus 2 according to the present embodiment can shift between a totally closed position (C) in which the door part 22 seals, by the lid part 43 held by the door part 22, the inner space 4S of the storage container body 42, and a totally open position (O) in which the lid part 43 held by the door part 22 is spaced apart from the storage container body 42 to fully open the inner space 4S forward and to the transfer room 3 of the storage container body 42. In the present embodiment, the attitude of the door part 22 positioned at the totally open position (O) shown in FIG. 8 is set to the same upright attitude of the door part 22 positioned at the totally closed position (C) shown in FIGS. 5 and 6. Also, the upright attitude is maintained while shifting between the totally open position (O) and the totally closed position (C). That is, the shifting route of the door part 22 between the totally open position (O) and the totally closed position (C) is formed by a route through which the door part 22 in the totally closed position (C) is shifted to the transfer room 3 while maintaining its height position (the horizontal route), and a route through which the door part 22 in the totally open position (O) is shifted upward while maintaining its front-rear position (the vertical route). At the point where the horizontal route and the vertical route cross each other, the shifting direction of the door part 22 is switched from the horizontal direction to the vertical direction, or from the vertical direction to the horizontal direction. The point where the horizontal route and the vertical route cross each other corresponds to “the shifting direction switching region” in the present invention. The shifting direction switching region in the present embodiment can be represented by one point. Accordingly. “the foremost position in the shifting direction switching region” and “the rearmost position in the shifting direction switching region” are the identical position. In the present embodiment, the position of the door part 22 arriving at the shifting direction switching region is referred to as “the shifting direction switching position (P)”. That is, at the point where the horizontal route and the vertical route cross each other, the door part 22 is positioned at the shifting direction switching position (P) shown in FIG. 7. As can be seen from FIG. 7, in order to allow the door part 22 positioned at the shifting direction switching position (P) to shift in either the vertical direction or the horizontal direction, the lid part 43 of the storage container 4 held by the door part 22 positioned at the shifting direction switching position (P) is positioned, together with the door part 22, at the forward position than the frame 21 (the position where the lid part 43 is fully spaced apart from the storage container body 42 and disposed in the inner space 3S of the transfer room 3).

Such shifting of the door part 22 is realized by a door shifting mechanism 27 provided at the door opening and closing apparatus 2. As shown in FIGS. 5 to 8, the door shifting mechanism 27 includes a support frame 271 supporting the door part 22, a movable block 273 that supports the support flame 271 via a slide support part 272 so as to be shiftable in the front-rear direction D, a slide rail 274 that supports the movable block 273 so as to be shiftable in the top-bottom direction H, and a drive source (e.g., a not-shown actuator) for causing the door part 22 to shift in the front-rear direction D along the horizontal route, and in the top-bottom direction H along the vertical route. By providing a drive instruction from the control unit 2C to this actuator, the door part 22 is caused to shift in the front-rear direction D and the top-bottom direction H. Note that, an actuator for the forward-back shift and an actuator for the up-down shift may be separately provided. Alternatively, a common actuator may be used as the drive source, thereby causing the door part to shift in the front-rear direction and the top-bottom direction.

The support frame 271 supports the rear lower portion of the door part 22. The support frame 271 has an approximate crank-shape which extends downward, passes through a slit-like insert hole 21b provided at the frame 21, and stretches to the outside of the transfer room 3 (on the placing pedestal 23 side). The slide support part 272 for supporting the support frame 271, the movable block 273, and the slide rail 274 are also disposed on the placing pedestal 23 side than the frame 21, that is, outside the transfer room 3. The slide support part 272, the movable block 273, and the slide rail 274 become sliding portions when the door part 22 is shifted. In the present embodiment, by virtue of disposing the foregoing components outside the transfer room 3 and designing the insert hole 21b to be small slit-like, even in the case where particles are generated while the door part 22 is shifting, entry of the particles into the transfer room 3 can be prevented or suppressed. Further, a cover 28 is provided to cover components or portions of the door shifting mechanism 27 disposed outside the transfer room 3, specifically, part of the support frame 271, the slide support part 272, the movable block 273, and the slide rail 274. Thus, the environmental gas in the transfer room 3 can be prevented from leaking outside the EFEM 1 via the insert hole 21b formed at the frame 21.

As shown in FIG. 1, the EFEM 1 mainly includes the door opening and closing apparatuses 2 (load ports) and the transfer room 3 which are provided adjacent to each other in a common clean room. The actuation of the EFEM 1 is controlled by the controller of each door opening and closing apparatus 2 (the control unit 2C shown in FIG. 2), or by a controller of the entire EFEM 1 (a control unit 3C shown in FIG. 1). For example, the processing apparatus M (a semiconductor processing apparatus) is provided adjacent to a wall surface 3B, which faces the wall surface 3A (the back surface) where the door opening and closing apparatuses 2 are disposed, of the transfer room 3.

In connection with the EFEM 1 according to the present embodiment, a plurality of (for example, three) door opening and closing apparatuses 2 are disposed along one wall surface 3A of the transfer room 3. As described above, in the present invention in which the frame 21 is defined to be on the front side and the storage container 4 is defined to be on the rear side in the front-rear direction D along which the storage container 4 and the frame 21 are aligned, the wall surface 3A, along which the door opening and closing apparatuses 2 are disposed, of the transfer room 3 can be regarded as the back surface.

In the clean room, the inner space MS of the processing apparatus M, the inner space 3S of the transfer room 3, and the inner space 4S of the storage container 4 placed on each of the door opening and closing apparatuses 2 are maintained at a high cleanliness level. On the other hand, the space where the door opening and closing apparatuses 2 are disposed, in other words, the outside of the processing apparatus M and the outside of the EFEM 1 are at a relatively low cleanliness level. Note that, FIG. 1 is a side view schematically showing the relative positional relationship between the door opening and closing apparatus(es) 2 and the transfer room 3, and the relative positional relationship between the EFEM 1 including the door opening and closing apparatus(es) 2 and the transfer room 3 and the processing apparatus M.

The processing apparatus M includes a load lock room disposed at the position relatively near to the transfer room 3, and a processing apparatus body disposed at the position relatively far from the transfer room 3. In the present embodiment, as shown in FIG. 1, in the front-rear direction D of the EFEM 1, the door opening and closing apparatus(es) 2, the transfer room 3, and the processing apparatus M are disposed in this order and in intimate contact with each other. Note that, actuation of the processing apparatus M is controlled by the controller of the processing apparatus M (a control unit MC shown in FIG. 1). Here, the control unit MC being the controller of the entire processing apparatus M or the control unit 3C being the controller of the entire EFEM 1 is a higher-level controller than the control unit 2C of the door opening and closing apparatus 2.

A transfer robot 31 is provided in the inner space 3S of the transfer room 3. The transfer robot 31 can transfer wafers W being the transfer target objects between the storage container 4 and the processing apparatus M. The transfer robot 31 includes, for example, an arm made up of a plurality of linkage elements coupled to each other so as to be turnable horizontally and having transfer target object gripping parts (hands 311) on its tip portion, and a running part that turnably supports an arm base structuring the proximal end of the arm and runs in the width direction of the transfer room 3 (the juxtaposed direction of the door opening and closing apparatuses 2). The transfer robot 31 has a linkage structure (a multijoint structure) in which the shape thereof changes between the folded state where the arm length is minimized and the stretched state where the arm length is longer than in the folded state. The transfer robot 31 may have a plurality of hands 311 in a multi-stage manner in the height direction. In the present embodiment, the transfer robot 31 of a so-called two hand type is employed, in which two hands 311 are provided in parallel to each other with a predetermined pitch between them in the height direction (the top-bottom direction H) at the tip of the arm. The actuation of the hands 311 can be controlled individually.

It is also possible to structure an EFEM 1 in which one of or both of a buffer station and an aligner are disposed on the side surface of the transfer room 3. In connection with the transfer room 3, by the door opening and closing apparatuses 2 and the processing apparatus M being connected, the inner space 3S is substantially sealed. Inside the inner space 3S of the transfer room 3, downflow being an air flow flowing downward is formed. Accordingly, even in the case where particles which may contaminate the surface of the wafers W exist in the inner space 3S of the transfer room 3, the particles can be pushed downward by the downflow, to thereby suppress the particles from attaching to the surface of the wafers W while being transferred. FIG. 1 schematically shows the flow of gas forming the downflow in the transfer room 3 as being represented by arrows.

In the present embodiment, the FOUP is employed as the storage container 4. The storage container 4 according to the present embodiment includes a storage container body 42 which is capable of opening the inner space 4S only forwardly via the transfer opening 41 formed at the front surface (the surface on the frame 21 side), and the lid part 43 capable of opening and closing the transfer opening 41. The storage container 4 is of a known structure, in which a plurality of wafers W being the transfer target objects are stored in a multistage manner in the top-bottom direction H, and the wafers W can be put in or taken out via the transfer opening 41.

The storage container body 42 integrally has a rear wall, a pair of right and left sidewalls, an upper wall, and a bottom wall. In the inner space 4S surrounded by the walls, a shelf part 421 (a wafer placing part) is provided in which the transfer target objects W can be placed by a plurality of stages and at a predetermined pitch. The boundary portion between the walls structuring the storage container body 42 forms a mild curved shape. Further, at the center of the upper surface of the upper wall, a flange part gripped by a storage container transfer apparatus (e.g., OHT: Over Head Transport) or the like is provided.

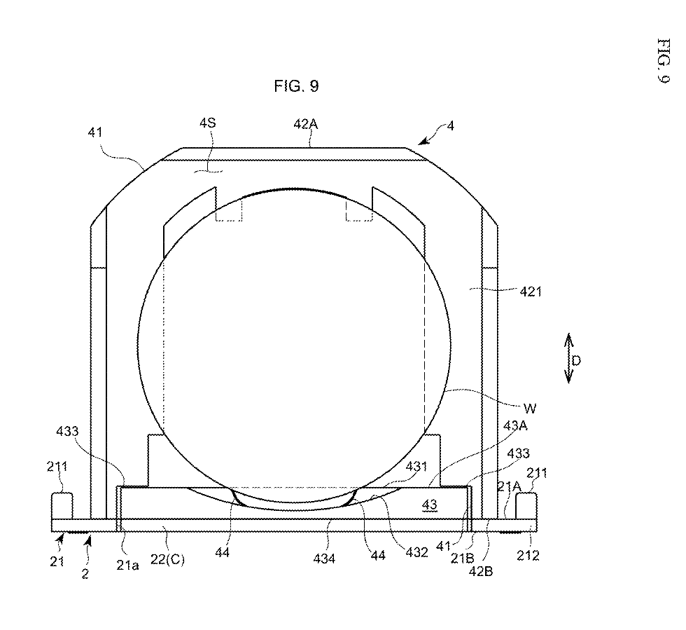

The lid part 43 faces the door part 22 of the door opening and closing apparatus 2 when the storage container 4 is placed on the placing pedestal 23 of the door opening and closing apparatus 2. The lid part 43 has an approximate plate-like shape. The height dimension of the lid part 43 is set to be substantially equal to the height dimension of the surface, which can be closely attached to the lid part 43, of the door part 22. Note that, FIG. 5 and others schematically show the lid part 43 set to have a height dimension slightly greater than the height dimension of the surface, which can be closely attached to the lid part 43, of the door part 22. The lid part 43 is provided with a latch part with which the lid part 43 can be locked to the storage container body 42. Then, as shown in FIG. 9 (a schematic cross-sectional view of the storage container 4 taken along a predetermined height position, the storage container 4 being closely attached to the frame 21 of the door opening and closing apparatus 2), retainers 44 capable of holding the edges of the transfer target objects W are provided at the inner surface 431, which faces the inner space 4S of the storage container body 42, of the lid part 43. Note that, FIG. 9 is not provided with hatching which represents the cross section.

In the present embodiment, the edge of the transfer target object W can be held by a pair of right and left retainers 44. The pairs of right and left retainers 44 are provided at the lid part 43 as many as the number of the transfer target objects W (the number of stages) that can be stored in the storage container 4. The transfer target objects W placed on the shelf part 421 are each held by a pair of retainers 44. Further, the lid part 43 according to the present embodiment is provided with, at a portion in the inner surface 431 that faces the transfer target objects W when the transfer opening 41 is closed by the lid part 43, a recessed part 432 being arc-shaped in a plan view and being recessed as compared to other portions. Specifically, in the inner surface 431 of the lid part 43, the recessed part 432 is formed across a predetermined position higher than the topmost transfer target object W and a predetermined position lower than the lowermost transfer target object W in the storage container 4 in the state where the transfer opening 41 is closed by the lid part 43, while the recessed part 432 is not formed at the upper end and the lower end of the inner surface 431. By providing such a recessed part 432 at the inner surface 431 of the lid part 43, even when the transfer target objects W of a great diameter are stored in the limited inner space 4S of the storage container 4 manufactured based on strict standards, contact or interference between the lid part 43 and the transfer target objects W is avoided.

In the present embodiment, the recessed part 432 is formed at a predetermined region including the center portion in the width direction of the inner surface 431 of the lid part 43. The retainers 44 are provided at the recessed part 432. Further, the lid part 43 according to the present embodiment is provided with gaskets 433 at the predetermined portions in the inner surface 431 that are brought into contact with or brought near to the storage container body 42 in the state where the transfer opening 41 is closed (in the example shown in the drawing, at the opposite sides of the inner surface 431). Since the gaskets 433 are brought into contact with the storage container body 42 taking precedence over the inner surface 431 of the lid part 43, and thus become elastically deformed, the inner space 4S of the storage container 4 can be totally sealed.

The retainers 44 are elastic, and project from the inner surface 431 of the lid part 43 inwardly (in the direction to be spaced apart from the inner surface 431 of the lid part 43). Further, in the present embodiment, the retainers 44 extend such that respective tip portions (projecting ends) of a pair of retainers 44 are gradually spaced apart from each other. In the tip portion of each of the retainers 44 that is in direct contact with the edge of the transfer target object W, a holding groove (not shown) is formed. Note that, when the transfer target objects W are the wafers provided with an alignment-purpose cutaway part (not shown) such as a notch at the edge, the distance between the tip portions of the retainers 44 in the state not holding the transfer target object W is preferably set to be greater than the opening width of the alignment-purpose cutaway part (not shown).

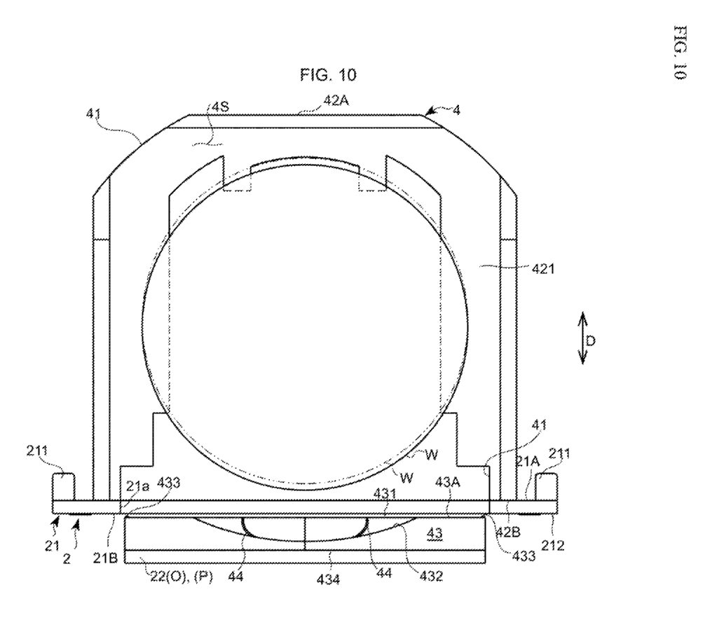

Such retainers 44 enter the non-holding state, shown in FIG. 10, not holding the edges of the transfer target objects W, when the lid part 43 is removed from the storage container body 42. On the other hand, when the lid part 43 is attached to the storage container body 42, the retainers 44 are brought into contact with the edge of the transfer target objects W stored in the storage container 4. Then, the retainers 44 shift in the direction in which the tip portions gradually approach the inner surface 431 of the lid part 43, while being elastically deformed as a whole and causing the edge of the transfer target objects W to be stored in the holding groove. In this manner, the retainer 44 changes (shifts) the position of the tip portions while being elastically deformed, between the holding state holding the edges of the transfer target objects W and the non-holding state. Note that, the tip portions of a pair of retainers 44 do not interfere with each other in both of the holding state and the non-holding state. The retainers 44 may be integrally or substantially integrally provided at the lid part 43. On the other hand, when the retainers 44 are removably attached to the lid part 43, just replacement of the retainer 44 can address any damage to the retainer 44. Further, the number of the retainers 44 holding one wafer may be one or three or more. The shape of the retainers 44 can be changed as appropriate. Such retainers 44 that function as wafer retainers by holding the wafers W stored in the storage container 4 while being elastically deformed from the inner surface 431 side of the lid part 43 are provided at the inner surface 431 of the lid part 43. This makes it possible to determine the position where the transfer target objects W are stored in the storage container 4, and to prevent any damage that may occur to the transfer target objects W being thin and fragile wafers or the like.

The storage container 4 according to the present embodiment is structured such that an outer surface 434 of the lid part 43 becomes flush with a front surface 42B of the storage container body 42, in the state where the transfer opening 41 of the storage container body 42 is totally sealed by the lid part 43.

The door opening and closing apparatus 2 according to the present embodiment performs a predetermined operation by the control unit 2C issuing drive instructions to the constituent members. Note that, in the present embodiment, it is structured such that the control unit 2C included in the door opening and closing apparatus 2 issues drive instructions to the constituent members. The control unit 2C includes a memory unit, ROM, RAM, an I/O port, a CPU, an input/output interface (IF) that exchanges data with an external display apparatus (not shown) and the like, and buses connecting the foregoing components to each other to transmit information.

The memory unit stores a control procedure corresponding to the type of the process performed in the door opening and closing apparatus 2. That is, the memory unit stores a predetermined operation program for each constituent member of the apparatus. Thus, the program according to the present embodiment is stored as a program capable of being performed by a non-transitory computer readable recording medium (a hard disk or the like).

The ROM includes a hard disk. EEPROM, flash memory or the like, and is a recording medium storing an operation program of the CPU or the like. The RAM functions as the work area of the CPU and the like. The 1/O port outputs, for example, control signals output from the CPU to the constituent members of the apparatus, and supplies information from sensors to the CPU.

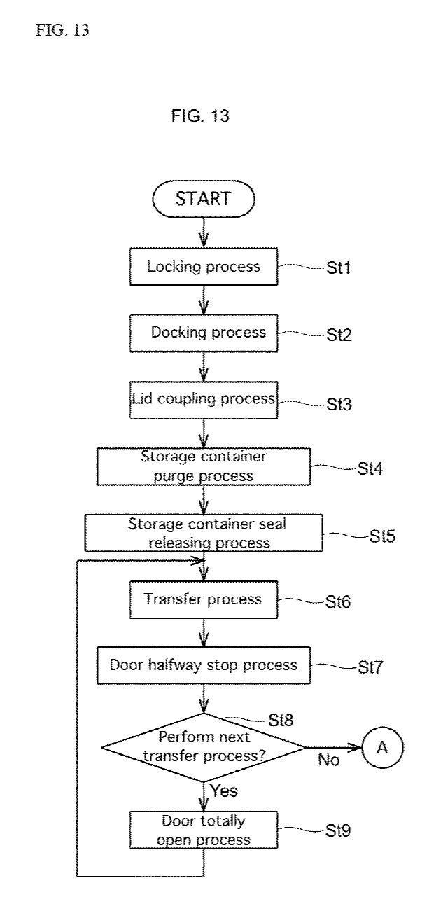

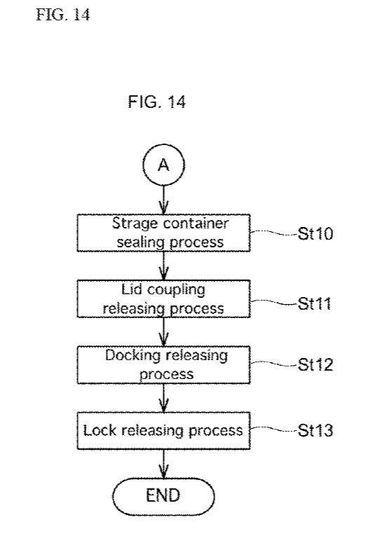

The CPU structures the center of the control unit 2C, and performs the operation program stored in the ROM. The CPU controls the operation of the door opening and closing apparatus in accordance with the program stored in the memory unit. The content of the program stored in the memory unit will be described together with the usage and operation of the EFEM 1 including the door opening and closing apparatus 2, with reference to FIGS. 13 and 14 and others showing the operation flow of the EFEM 1.

Firstly, by a storage container transfer apparatus such as an OHT that operates on a linear transfer line (a traffic line) extending along the common wall surface 3A, along which the door opening and closing apparatuses 2 are disposed, of the transfer room 3, the storage container 4 is transferred to the point above each door opening and closing apparatus 2, and placed on the placing pedestal 23. At this time, for example the positioning projections 231 provided at the placing pedestal 23 fit in the positioning recess parts of the storage container 4. Further, the control unit 2C causes the lock claw 232 on the placing pedestal 23 to enter the locked state (a locking process St1). Specifically, by hooking, on the lock receiving part (not shown) provided at the bottom surface of the storage container 4, the lock claw 232 on the placing pedestal 23 and fixing thereto, the locked state is entered. Thus, the storage container 4 can be placed at a predetermined normal position on the placing pedestal 23 and fixed thereto.

In the present embodiment, the storage container 4 can be placed on the placing pedestal 23 of each of the door opening and closing apparatuses 2 disposed by three in number so as to be juxtaposed to each other in the width direction of the transfer room 3. Further, it is also possible to structure such that a seat sensor (not shown) that detects whether or not the storage container 4 is placed on the placing pedestal 23 at a predetermined position detects that the storage container 4 is placed at a normal position on the placing pedestal 23.

Next, in each door opening and closing apparatus 2 according to the present embodiment, the control unit 2C causes the placing pedestal 23 at the position shown in FIG. 5 to advance toward the frame 21 until reaching the position shown in FIG. 6. Thus, the front surface of the storage container 4 (specifically, the front surface 42B of the storage container body 42) is brought into contact with a frame rearmost surface 21A, which is situated at the circumference of the opening 21a and nearest to the storage container body 42, of the frame 21 (a docking process St2). Subsequently, in each door opening and closing apparatus 2 according to the present embodiment, the control unit 2C switches the coupling mechanism 221 to the lid coupled state (a lid coupling process St3). This process allow the door part 22, which is previously on standby at the totally closed position (C), to couple to the lid part 43 with the coupling mechanism 221 and to hold in the closely attached state. Further, the state where the lid part 43 is removable from the storage container body 42 is entered.

Further, in each door opening and closing apparatus 2 according to the present embodiment, at the time point where the storage container 4 is placed at the normal position on the placing pedestal 23, the control unit 2C detects that the bottom surface part of the storage container 4 has pressed the pressed part of, for example, a pressure sensor provided at the placing pedestal 23. This triggers the control unit 2C to issue a drive instruction (signal) of advancing the bottom purge injection nozzle 261 and the bottom purge discharge nozzle 261 provided at the placing pedestal 23 to be higher than the upper surface of the placing pedestal 23. As a result, the nozzles 261 (the bottom purge injection nozzle, the bottom purge discharge nozzle) are coupled to the injection port and the discharge port of the storage container 4, and the state where the purge process can be performed is entered.

Then, in each door opening and closing apparatus 2 according to the present embodiment, the control unit 2C issues a drive instruction, to perform the purge process on the inner space 4S of the storage container 4 (a storage container purge process St4). In the storage container purge process St4, a predetermined environmental gas is supplied to the inner space 4S of the storage container 4 from the bottom purge injection nozzle 261 via the injection port, and gas with which the inner space 4S of the storage container 4 has been filled is discharged from the bottom purge discharge nozzle 261 via the discharge port. By the purge process, the inner space 4S of the storage container 4 is filled with the environmental gas, and the moisture concentration and the oxygen concentration in the storage container 4 are respectively reduced to be equal to or lower than predetermined values in a short time period. Thus, the ambient environment of the transfer target objects W in the storage container 4 attains a low humidity environment and a low oxygen environment.

Note that, the storage container 4 may be previously subjected to the purge process at a time point before being placed on the placing pedestal 23. Specific examples of the timing at which the purge process is previously performed at the time point before the storage container 4 is placed on the placing pedestal 23 of the door opening and closing apparatus 2 may be: the time point where the storage container 4 is stored in a storage capable of storing a plurality of storage containers; the time point where the storage container 4 is placed on a dedicated purge station other than the door opening and closing apparatus 2; and any appropriate time point during the manufacturing process in another transfer target object manufacturing apparatus or after the manufacture. To the storage container 4 having previously undergone the purge process at a time point before being placed on the placing pedestal 23, the storage container purge process St4 may be or may not be performed. The advantage in performing the storage container purge process St4 also to the storage container 4 having previously undergone the purge process at a time point before being placed on the placing pedestal 23 is as follows. That is, even with the storage container 4 having previously undergone the purge process at a time point before being placed on the placing pedestal 23, a slight amount of the environmental gas may leak from inside the storage container 4. As the time elapses from the time point where the purge process has completed before being placed on the placing pedestal 23, the moisture concentration and the oxygen concentration in the storage container 4 rise. Accordingly, by performing the storage container purge process St4, the moisture concentration and the oxygen concentration in the storage container 4 can be reduced, and thus the gas atmosphere in the storage container 4 is replaced by a gas atmosphere of high cleanliness.

Subsequently, in each door opening and closing apparatus 2 according to the present embodiment, the control unit 2C performs the process of shifting the door part 22 by the door shifting mechanism 27 frontward (toward the transfer room 3) by a predetermined distance from the totally closed position (C), to open the opening 21a of the frame 21 and the transfer opening 41 of the storage container 4, thereby releasing the sealed state of the storage container 4 (a storage container seal releasing process St5). Specifically, as shown in FIGS. 7 and 8, the control unit 2C shifts the door part 22 by a predetermined distance along the horizontal route from the totally closed position (C) toward the transfer room 3. Further, as shown in FIGS. 7 and 8, the control unit 2C lowers the door part 22 arriving at the shifting direction switching position (P) by a predetermined distance along the vertical route to position the door part 22 at the totally open position (O). As a result, the closed state of the opening 21a of the frame 21 and the transfer opening 41 of the storage container 4 is released, whereby the inner space 48 of the storage container 4 enters the seal released state where the inner space 4S is opened frontward (toward the transfer room 3) via the opening 21a.

Then, in the state where the storage inner space 4S of the container body 42 and the inner space 3S of the transfer room 3 communicate with each other, the transfer robot 31 provided in the inner space 3S of the transfer room 3 performs an access operation to the inside of the storage container 4, and performs a transfer process of the transfer target objects W (a transfer process St6). Note that, it is also possible to provide the door opening and closing apparatuses 2 or the EFEM 1 with, for example, an optical door sensor that detects shifting of the door part 22. In this case, it is possible to perform, prior to the transfer process St6, a process of sensing that the door part 22 is not positioned at the totally closed position (C), that is, sensing that the access operation of the transfer robot 31 to the inner space 4S of the storage container 4 is enabled (a door open sensing process). As the door open sensing process, it is possible to employ the process in which the up-down distance of the door part 22 is sensed by the door shifting mechanism 27 in place of the sensing process through use of the door sensor, to thereby sense that the door part 22 is not positioned at the totally closed position (C), that is, the access operation of the transfer robot 31 to the inner space 4S of the storage container 4 is enabled.

Here, in the present embodiment, since the transfer robot 31 having two hands 311 is employed, two transfer target objects W at a maximum can be transferred by a single access operation of the transfer robot 31 to the storage container 4. Specifically, when the transfer robot 31 according to the present embodiment transfers two transfer target objects W by a single access operation to the storage container 4, the content of the transfer process that can be performed in the transfer process St6 is as follows.

The first process content is a process of the transfer robot 31 taking out a transfer target object W from the storage container 4 with one hand (the first hand) out of the two hands 311, and thereafter taking out a transfer target object W from the storage container 4 with the other hand (the second hand). The second process content is a process of taking out a transfer target object W from the storage container 4 with the first hand, and thereafter putting in a transfer target object W having undergone any appropriate process by the manufacturing apparatus M into the storage container 4 with the second hand. The third process content is a process of putting in a transfer target object W having undergone the process into the storage container 4 with the first hand, and thereafter taking out a transfer target object W from the storage container 4 with the second hand. The fourth process content is a process of putting in the transfer target object W having undergone the process into the storage container 4 with the first hand, and thereafter putting in a transfer target object W having undergone the process into the storage container 4 with the second hand. The transfer robot 31 performs any process appropriately selected out of the foregoing process contents. Note that, the transfer target object W transferred by the first hand and the transfer target object W transferred by the second hand in a single access operation to the storage container 4 are preferably stored on adjacent stages in the storage container 4 in the height direction H during the process of taking out, or stored on adjacent stages in the storage container 4 in the height direction H during the process of taking in. Note that, even when the transfer robot 31 having a plurality of hands is employed, it is possible to select a process of transferring the transfer target object W smaller in number than the hands (one transfer target object W in the present embodiment) in a single access operation of the transfer robot 31 to the storage container 4.

For example, when the transfer target objects W in the storage container 4 are transferred into the transfer room 3 by the transfer process St6, the transfer target objects W transferred into the transfer room 3 are transferred by the transfer robot 31 to the processing apparatus M (specifically, the load lock room), the buffer station, or the aligner.

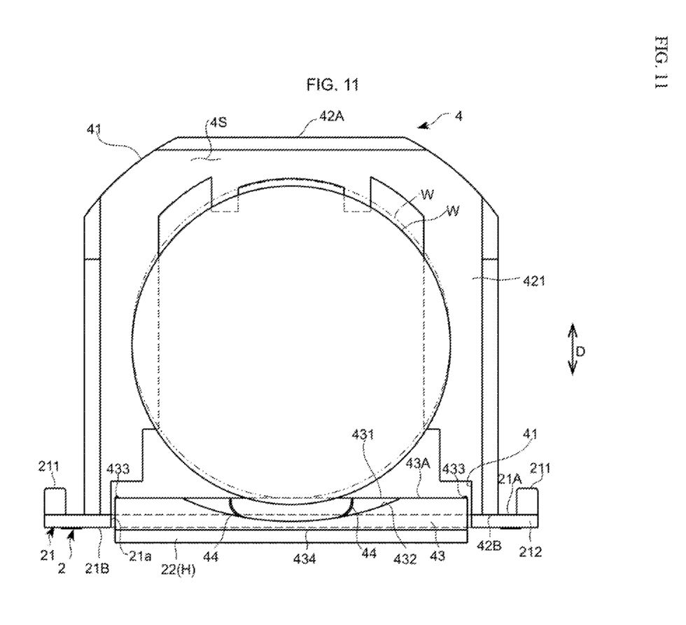

Then, with each door opening and closing apparatus 2 according to the present embodiment, every time a single access operation of the transfer robot 31 to the storage container 4 ends, the control unit 2C performs the process of shifting the door part 22 by the door shifting mechanism 27 from the totally open position (O) to a predetermined halfway stop position (H) shown in FIG. 11 (a door halfway stop process St7). In the present embodiment, before the transfer robot 31 performs an access operation to the inside of the storage container 4 and performs the transfer process of the transfer target objects W, the door part 22 is positioned at the totally open position (O) in the storage container seal releasing process St5. Therefore, this process of shifting the door part 22 to the halfway stop position (H) (the door halfway stop process St7) is as follows. That is, by the process of shifting, by the door shifting mechanism 27, the door part 22 upward along the vertical route from the totally open position (O) and shifting the door part 22 arriving at the shifting direction switching position (P) by a predetermined distance toward the storage container body 42 along the horizontal route, the door part 22 can be shifted to the halfway stop position (H).

The process of shifting the door part 22 by the door shifting mechanism 27 to the halfway stop position (H) and stopping the door part 22 thereto is realized by converting the shift amount of the door part 22 itself into numbers and controlling the parameters. Note that, the process of shifting the door part 22 by the door shifting mechanism 27 to the halfway stop position (H) and stopping the door part 22 thereto may be mechanically achieved through use of components such as a stopper.

Here, the timing at which the door part 22 is shifted from the totally open position (O) to the halfway stop position (H) at and after the time point where a single access operation of the transfer robot 31 to the storage container 4 ends and the transfer process by that access operation ends may be any timing at which the door part 22 or the lid part 43 and the transfer robot 31 do not interfere with each other. Note that, if it is the timing at which the door part 22 or the lid part 43 and the transfer robot 31 do not interfere with each other, the door part 22 may be shifted to the halfway stop position (H) immediately after completion of an access operation of the transfer robot 31 to the storage container 4. Further, when the door part 22 or the lid part 43 and the transfer robot 31 would interfere with each other if the door part 22 is shifted from the totally open position (O) to the halfway stop position (H) immediately after completion of an access operation of the transfer robot 31 to the storage container 4, the door part 22 should be shifted from the totally open position (O) to the halfway stop position (H) after a lapse of a predetermined time period from a time point immediately after completion of an access operation of the transfer robot 31 to the storage container 4.

In the present embodiment, the door part 22 is put on standby at the halfway stop position (H) from the end of a single access operation of the transfer robot 31 to the storage container 4 until immediately before execution of next access operation of the transfer robot 31 to the storage container 4.

The halfway stop position (H) is a predetermined position on the front side than the totally closed position (C), and where the rearmost inner surface 43A, which is nearest to the back surface 42A of the storage container body 42, of the inner surface 431 of the lid part 43 is on the rear side (on the back surface 41A side of the storage container 4) than the frame foremost surface 211B of the frame 21. The frame foremost surface 21B of the frame 21 is the surface, which is situated at the circumference of the opening 21a and farthest from the storage container body 42, of the frame 21. In the present embodiment employing the frame 21 including a pair of right and left support struts 211 and the frame body 212 supported by the support struts 211, “the frame foremost surface 21B being the surface, which is situated at the circumference of the opening 21a and farthest from the storage container body 42, of the frame 21” refers to the front surface of the frame body 212. That is, the frame foremost surface 21B can be regarded as the surface defining the position in the front-rear direction D of the foremost opening edge (opening front edge) in the opening 21a.

In the present embodiment, as shown in FIG. 11, the position where the entire rearmost inner surface 43A of the lid part 43 is on the rear side than the frame foremost surface 21B and where elasticity of the retainers 44 does not act (the position where the retainers 44 can maintain the non-holding state) is set as the halfway stop position (H). Specifically, the position of the door part 22 where the entire rearmost inner surface 43A of the lid part 43 is on the rear side than the frame rearmost surface 21A and the front surface 42B of the storage container body 42 and where elasticity of the retainers 44 does not act is set as the halfway stop position (H). More specifically, the position of the door part 22 where the entire rearmost inner surface 43A of the lid part 43 is on the rear side than the front surface 42B of the storage container body 42, reaching half or substantially half the distance in the front-rear direction D of the transfer opening 41 formed at the front end of the storage container body 42, and elasticity of the retainers 44 does not act is set as the halfway stop position (H). In the range within which the elasticity of the retainers 44 does not act, the position of the door part 22 where the rearmost inner surface 43A of the lid part 43 reaches a further rearward position than half the distance in the front-rear direction D of the transfer opening 41 can be set as the halfway stop position. Further, it is also possible to set the position of the door part 22 where the entire rearmost inner surface 43A of the lid part 43 is on the rear side than the front surface 42B of the storage container body 42, and reaches a frontward position than half the distance in the front-rear direction D of the transfer opening 41 as the halfway stop position. In the present embodiment, the storage container 4 in which the recessed part 432 is formed at the inner surface 431 of the lid part 43 is employed. In this case, the recessed part 432 is a portion (a surface) that is far from the back surface 42A of the storage container body 42 than the portion in the inner surface 431 of the lid part 43 not forming the recessed part 432. Accordingly, the recessed part 432 does not correspond to the rearmost inner surface 43A. Further, the retainers 44 according to the present embodiment have the shape and dimension in which, in the state not exhibiting elasticity (the non-holding state), the entire retainers 44 (the entire retainers including the retainer tip portions nearest to the back surface 42A of the storage container body 42) are accommodated in the recessed region of the recessed part 432.

Note that, it is also possible to employ retainers having the shape and dimension in which part of the retainers is not accommodated in the recessed region of the recessed part 432 in the non-holding state. In this case also, since the retainers themselves do not correspond to “the inner surface”, the retainers partially or entirely will not act as the surface corresponding to “the rearmost inner surface of the lid part”. In the present embodiment, as shown in FIG. 11, when the door part 22 is positioned at the halfway stop position (H), the front edge portion of the transfer target object W at the tentative storage position represented by a solid line in FIG. 11 is stored in the recessed region of the recessed part 432. Further, as shown in FIG. 11, when the door part 22 is positioned at the halfway stop position (H), the front edge portion of the transfer target object W at the normal storage position represented by a phantom line (a chain double-dashed line) in FIG. 11 is not accommodated in the recessed region of the recessed part 432. As can be seen from FIG. 11, in the present embodiment, the position of the door part 22 where the retainers 44 are in close proximity to the edge of the transfer target object W stored in the storage container 4 and where elasticity of the retainers 44 does not act is set as the halfway stop position (H).

In each door opening and closing apparatus 2 according to the present embodiment, when the transfer robot 31 performs next access operation to the storage container 4 (St8: Yes in FIG. 13), the control unit 2C shifts the door part 22 from the halfway stop position (H) to the totally open position (O) at a time point before the transfer robot 31 performs next access operation to the storage container 4 (a door totally open process St9). After the door totally open process St9, the transfer robot 31 performs next access operation to the storage container 4, and performs the transfer process St6.

In each door opening and closing apparatus 2 of the present embodiment, every time the transfer robot 31 performs an access operation to the storage container 4 and finishes one transfer process, an instruction as to whether or not next access operation is performed by the transfer robot 31 to the storage container 4 is issued. Then, when the transfer robot 31 performs next access operation to the storage container 4 (St8: Yes in FIG. 13), the door totally open process St9 and the transfer process St6 are performed in this order, and the door part 22 is put on standby at the halfway stop position (H) until immediately before the transfer robot 31 performs the next access operation to the storage container 4 (a door halfway stop process St7). In this manner, the door opening and closing apparatus 2 according to the present embodiment is characterized in that the door halfway stop process St7 is performed every time a single access operation of the transfer robot 31 to the storage container 4 ends.

In the present embodiment including the foregoing process steps, as compared to the mode in which the door part 22 is kept on standby at the totally open position (O) from the start of the transfer process St6 of the transfer target objects W in the storage container 4 until the end of the transfer processes of all the transfer target objects W, every time a single access operation of the transfer robot 31 to the storage container 4 ends, the door part 22 is put on standby at the halfway stop position (H), and with the lid part 43 held by the door part 22, the frontward opened region of the inner space 4S of the storage container 4 can be regulated. As a result, the ambient atmosphere of the transfer target objects W stored in the inner space 4S of the storage container 4 can be maintained at a predetermined low moisture concentration and a low oxygen concentration. Note that, a high moisture concentration and a high oxygen concentration in the storage container 4 indicate that the purge concentration in the storage container 4 is low.

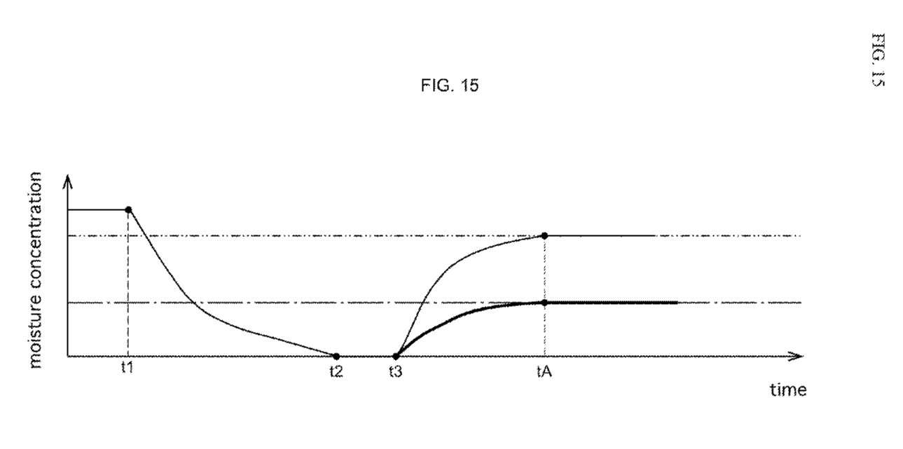

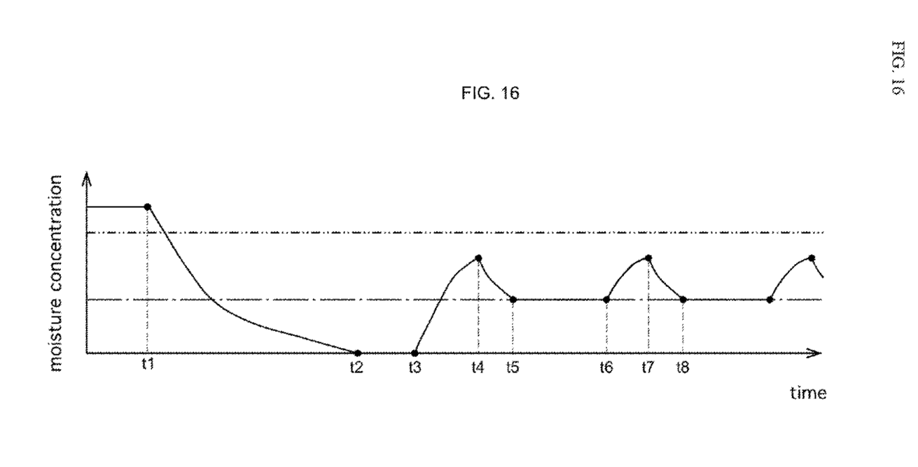

Here, with reference to FIGS. 15 and 16, a description will be given of changes in the moisture concentration in the inner space 4S of the storage container 4. The moisture concentration in the inner space 4S of the storage container 4 is at a high value until a time point t1 where the purge process is started with the door part 22 positioned at the totally closed position (C). Then, at a time point t2 where a predetermined time period has elapsed from the start of the purge process, the moisture concentration in the inner space 4S of the storage container 4 becomes zero or substantially zero. By continuously performing the purge process with the door part 22 positioned at the totally closed position (C), the moisture concentration in the inner space 4S of the storage container 4 can be kept at zero or substantially zero. Then, as shown in FIG. 15, at and after a time point t3 where the door part 22 is started to shift from the totally closed position (C) to the totally open position (O), the moisture concentration in the inner space 4S of the storage container 4 sharply rises. At a time point tA where a predetermined time period has elapsed since the door part 22 is kept on standby at the totally open position (O), the rising trend of the moisture concentration in the inner space 4S of the storage container 4 stops. At and after the time point tA, the moisture concentration in the inner space 4S of the storage container 4 maintains the high value. That is, inside the storage container 4 is disadvantageously maintained in a high moisture concentration state. In FIG. 15, the maximum value of the moisture concentration in the storage container 4 when the door part 22 is continuously kept on standby at the totally open position (O) (the maximum value in the totally open position standby state) is represented by a chain double-dashed line.

Further, FIG. 15 shows, by a relatively bold solid line, changes in the moisture concentration in the storage container 4 when the door part 22 is shifted from the totally closed position (C) to the halfway stop position (H), and continuously kept on standby at the halfway stop position (H). In this case, at and after the time point t3 where the door part 22 is started to shift from the totally closed position (C) to the halfway stop position (H), the moisture concentration in the inner space 4S of the storage container 4 rises. However, when the door part 22 is shifted from the totally closed position (C) to the halfway stop position (H) and kept on standby at the halfway stop position (H), the rising trend of the moisture concentration in the inner space 4S of the storage container 4 stops at the time point tA where a predetermined time period has elapsed. Then, at and after the time point tA, the moisture concentration in the inner space 4S of the storage container 4 is maintained at a lower value than the maximum value in the totally open position standby state represented by the chain double-dashed line in FIG. 15. That is, the inside of the storage container 4 is maintained in an excellent low moisture-concentration state. In the case where the door part 22 is continuously kept on standby at the halfway stop position (H), being different from the case where the door part 22 is positioned at the totally closed position (C), the inner space 4S of the storage container 4 is not sealed. Accordingly, the maximum value of the moisture concentration in the storage container 4 in the case where the door part 22 is continuously kept on standby at the halfway stop position (H) (the maximum value in the halfway stop position standby state) will not become zero. FIG. 15 shows the maximum value in the halfway stop position standby state by an alternate long and short dashed line.

In the present embodiment, as described above, the purge process is performed on inside the storage container 4 on the placing pedestal 23 with the door part 22 positioned at the totally closed position (C). Then, before a first access operation of the transfer robot 31 to the storage container 4 having undergone the purge process is started, the door part 22 is shifted from the totally closed position (C) to the totally open position (O). This process procedure is similar to the conventional process procedure up to this point. However, in the present embodiment, as described above, every time a single access operation of the transfer robot 31 to the storage container 4 ends, the door part 22 is shifted from the totally open position (O) to the halfway stop position (H) and put on standby. In this case, the moisture concentration in the inner space 4S of the storage container 4 shows changes as shown in FIG. 16.

That is, when the door part 22 is shifted from the totally closed position (C) to the totally open position (O) by the storage container seal releasing process St5 immediately before the transfer robot 31 starts the first access operation to the storage container 4 having undergone the purge process, at and after the time point (the time point where the door part 22 is started to shift from the totally closed position (C) to the totally open position (O)) t3, the moisture concentration in the inner space 4S of the storage container 4 rises. However, after a single access operation of the transfer robot 31 to the storage container 4 ends, by performing the process in which the door part 22 is positioned at the halfway stop position (H), and put on standby at the halfway stop position (H) until immediately before next access operation of the transfer robot 31 to the storage container 4 is performed (the door halfway stop process St7), the rising of the moisture concentration in the inner space 4S of the storage container 4 stops. That is, at the time point t4 where the door part 22 is shifted from the totally open position (0) to the halfway stop position (H), the rising of the moisture concentration in the inner space 4S of the storage container 4 stops.

By setting the time period from the time point t3 where the door part 22 is started to shift from the totally closed position (C) to the totally open position (O) to the time point t4 where the door part 22 is shifted from the totally open position (O) to the halfway stop position (H) (the time period obtained by equation “t4−t3”) to be shorter than a predetermined time period, the maximum value of the moisture concentration in the storage container 4 at and after the time point t4 where the door part 22 is shifted from the totally open position (O) to the halfway stop position (H) will not rise to assume the maximum value in the totally open position standby state represented by the chain double-dashed line in FIGS. 15 and 16, and assumes a value lower than the maximum value in the totally open position standby state.

Then, by performing the door halfway stop process St7 of putting the door part 22 on standby at the halfway stop position (H) from the end of the access operation of the transfer robot 31 to the storage container 4 until immediately before execution of next access operation of the transfer robot 31 to the storage container 4, the moisture concentration in the inner space 4S of the storage container 4 reduces. At and after the time point t4 where the door part 22 is shifted from the totally open position (O) to the halfway stop position (H), at the time point t5 where a predetermined time period has elapsed since the door part 22 is put on standby at the halfway stop position (H), the moisture concentration in the inner space 4S of the storage container 4 assumes the value identical to the maximum value in the halfway stop position standby state represented by the alternate long and short dashed line in FIGS. 15 and 16. By further continuously keeping the door part 22 on standby at the halfway stop position (H), the moisture concentration in the inner space 4S of the storage container 4 is maintained at the value identical to the maximum value in the halfway stop position standby state. That is, the inside of the storage container 4 is maintained in an excellent low moisture-concentration state.

Note that, in the case where the time period from the time point t3 where the door part 22 is started to shift from the totally closed position (C) to the totally open position (O) until the time point t4 where the door part 22 is shifted from the totally open position (O) to the halfway stop position (H) is set to be longer than a predetermined time period, it is expected that the maximum value of the moisture concentration in the storage container 4 that rises at and after the time point t3 where the door part 22 is started to shift from the totally closed position (C) to the totally open position (O) assumes the value identical to the maximum value in the totally open position standby state. However, at and after the time point where the door part 22 is shifted from the totally open position (O) to the halfway stop position (H), by putting the door part 22 on standby at the halfway stop position (H), the moisture concentration in the inner space 4S of the storage container 4 reduces. Then, at and after the time point where the door part 22 is shifted from the totally open position (O) to the halfway stop position (H), at the time point where a predetermined time period has elapsed since the door part 22 is put on standby at the halfway stop position (H), it is assumed that the moisture concentration in the inner space 4S of the storage container 4 assumes the value identical to the maximum value in the halfway stop position standby state. Further, as described above, the moisture concentration in the inner space 4S of the storage container 4 is maintained at the value identical to the maximum value in the halfway stop position standby state by continuously keeping the door part 22 on standby at the halfway stop position (H).

In the present embodiment, before the transfer robot 31 starts next access operation to the storage container 4, the door part 22 is shifted from the halfway stop position (H) to the totally open position (O) (the door totally open process St9). At the time point t6 where the door part 22 is started to shift from the halfway stop position (H) to the totally open position (O), the moisture concentration of the inner space 4S of the storage container 4 again rises. However, by keeping the door part 22 on standby at the halfway stop position (H) from the end of the next access operation of the transfer robot 31 to the storage container 4 until immediately before execution of further next access operation of the transfer robot 31 to the storage container 4, the moisture concentration of the inner space 4S of the storage container 4 can be prevented from again rising. That is, at and after the time point t7 where the door part 22 is shifted from the totally open position (O) to the halfway stop position (H), the moisture concentration of the inner space 4S of the storage container 4 does not rise but instead reduces. Then, at and after the time point t7 where the door part 22 is shifted from the totally open position (O) to the halfway stop position (H), at the time point t8 where a predetermined time period has elapsed since the door part 22 is put on standby at the halfway stop position (H), the moisture concentration in the inner space 4S of the storage container 4 assumes the value identical to the maximum value in the halfway stop position standby state. Further, by continuously keeping the door part 22 on standby at the halfway stop position (H), the moisture concentration in the inner space 4S of the storage container 4 is maintained at the value identical to the minimum value in the halfway stop position standby state.

Note that, the changes in the oxygen concentration in the inner space 4S of the storage container 4 appear identically or similarly to the changes in the moisture concentration in the inner space 4S of the storage container 4.

In this manner, with each door opening and closing apparatus 2 according to the present embodiment, as compared to the mode in which the door part 22 is kept on standby at the totally open position (O) from the start of the transfer process of the transfer target objects W in the storage container 4 until the end of the transfer processes of all the transfer target objects W, it becomes possible to prevent the inner space 4S of the storage container 4 from keeping a high moisture concentration and a high oxygen concentration for a long period, and the inner space 4S of the storage container 4 can be maintained at a low moisture concentration and a low oxygen concentration.

Further, with each door opening and closing apparatus 2 according to the present embodiment, the rearmost inner surface 43A of the lid part 43 held by the door part 22 on standby at the halfway stop position (H) is positioned to be near to the inner space 4S of the storage container 4, passing through the opening 21a formed at the frame 21. As a result, the clearance in the front-rear direction D between the portion of the storage container body 42 to which the lid part 43 would be closely attached in the sealed state, and the lid part 43 held by the door part 22 on standby at the halfway stop position (H) can be reduced.

Here, a description will be given of the position of a transfer target object W at a time point where the transfer target object W is put in the storage container 4 using the transfer robot 31. At a time point where a transfer target object W is put in the storage container 4 using the transfer robot 31, while the transfer target object W is placed on the shelf part 421 in the storage container 4, as shown in FIG. 10, the transfer target object W is placed at a slightly frontward position than the normal storage position on the shelf part 421 for example by 2 mm to 3 mm (in the direction becoming spaced apart from the back surface 42A of the storage container body 42) (a tentative storage position). In FIG. 10, the transfer target object W at the tentative storage position is represented by a solid line, and the transfer target object W at the normal storage position is represented by a phantom line (a chain double-dashed line). As shown in FIG. 11, in the case where the door part 22 is positioned at the halfway stop position (H) also, the transfer target object W on the shelf part 421 does not shift and stays at the tentative storage position. In FIG. 11 also, the transfer target object W at the tentative storage position is represented by a solid line, and the transfer target object W at the normal storage position is represented by a phantom line (a chain double-dashed line).

To the transfer target object W placed at the tentative storage position on the shelf part 421, the door opening and closing apparatus 2 according to the present embodiment can determine the storage position of the transfer target object W in the storage container 4 in the course of shifting the door part 22 not at the totally closed position (C) to the totally closed position (C). That is, when the state where the inner space 4S of the storage container 4 is not sealed transits to the state where the inner space 4S of the storage container 4 is totally sealed by the lid part 43, the retainers 44 provided at the inner surface 431 of the lid part 43 abut on the edge of the transfer target object W and become elastically deformed. This causes the transfer target object W to shift to the normal storage position on the shelf part 421, and the storage position of the transfer target object W in the storage container 4 can be determined.

In each door opening and closing apparatus 2 according to the present embodiment, when all the transfer target objects W in the storage container 4 have undergone the process by the processing apparatus M, the control unit 2C performs the process which is performed when the next transferring process is not performed (St8: No in FIG. 13). That is, the control unit 2C performs the process of causing the door shifting mechanism 27 to shift the door part 22 to the totally closed position (C); thereby closing the opening 21a of the frame 21 and the transfer opening 41 of the storage container 4; and thereby sealing the inner space 4S of the storage container 4 (a storage container sealing process St10, see FIG. 14). Specifically, as shown in FIGS. 7 and 8, the control unit 2C causes the door part 22 to rise by a predetermined distance along the vertical route, to shift from the totally open position (O) to the shifting direction switching position (P). Subsequently, the control unit 2C shifts the door part 22 arriving at the shifting direction switching position (P) in the direction to be away from the transfer room 3 (rearward) by a predetermined distance along the horizontal route. As a result, the opening 21a of the frame 21 and the transfer opening 41 of the storage container 4 are closed, whereby the inner space 4S of the storage container 4 is sealed.

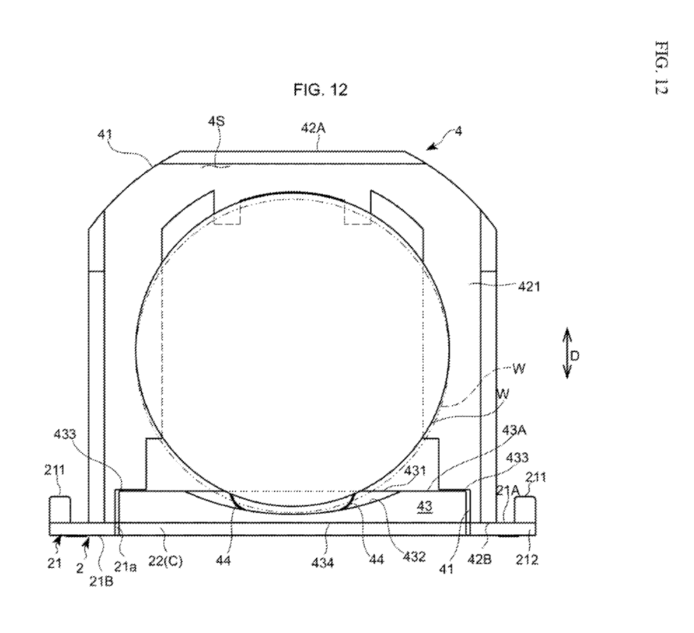

In accordance with the storage container sealing process St10, as shown in FIG. 12, the retainers 44 provided at the inner surface 431 of the lid part 43 hold the edges of the transfer target objects W while being elastically deformed, and all the transfer target objects W stored in the storage container 4 can be shifted from the tentative storage position on the shelf part 421 to the normal storage position and the position thereof can be determined. In FIG. 12, the transfer target object W at the normal storage position is represented by a solid line, and the transfer target object W at the tentative storage position is represented by a phantom line (a chain double-dashed line). Note that, the storage container purge process St4 in the present embodiment can be continuously performed until the end time point of the storage container sealing process St10. It is also possible to end or temporarily end the storage container purge process St4 at any appropriate time point before the end of the storage container sealing process St10, in order to reduce the use amount and use time of the environmental gas required for the storage container purge process St4.

Subsequently to the storage container sealing process St10, in each door opening and closing apparatus 2 according to the present embodiment, the control unit 2C switches the coupling mechanism 221 from the lid coupled state to the lid coupling released state (a lid coupling releasing process St11). By this process, the coupled state between the door part 22 and the lid part 43 can be released, and the lid part 43 can be attached to the storage container body 42. Next, in each door opening and closing apparatus 2 according to the present embodiment, the control unit 2C backs off the placing pedestal 23 in the direction becoming spaced apart from the frame 21 (a docking releasing process St12). Further, the control unit 2C releases the state where the storage container 4 is locked by the lock claw 232 on the placing pedestal 23 (a lock releasing process St13). Specifically, the locked state of the lock claw 232 to the lock receiving part provided at the bottom surface of the storage container 4 is released. Thus, the storage container 4 storing the transfer target objects W having undergone a predetermined process are passed from the placing pedestal 23 of each door opening and closing apparatus 2 to the storage container transfer apparatus, and transferred to the next process.

As described above, each door opening and closing apparatus 2 according to the present embodiment is structured such that, every time a single access operation of the transfer robot 31 to the storage container 4 ends and until immediately before next access operation of the transfer robot 31 to the storage container 4 is performed, the door part 22 is put on standby at the predetermined halfway stop position (H) which is on the front side than the totally closed position (C) and where the rearmost inner surface 43A of the lid part 43 is on the rear side than the frame foremost surface 21B.

With the door opening and closing apparatus 2 of the present embodiment structured as described above, the inner space 4S of the storage container 4 can be blocked in the front-rear direction D by the lid part 43 held by the door part 22 on standby at the halfway stop position (H). In particular, by positioning the rearmost inner surface 43A of the lid part 43 held by the door part 22 put on standby at the halfway stop position (H) on the rear side than the opening front edge of the opening 21a formed at the frame 21, it becomes possible to reduce the clearance in the front-rear direction D between the portion of the lid part 43 and the portion of the storage container body 42 which would be closely attached to each other in the front-rear direction D in the sealed state. Further, with the door opening and closing apparatus 2 according to the present embodiment, it becomes possible to shorten the time period during which the entire inner space 4S of the storage container 4 is totally opened toward the transfer room 3 which continues until all the transfer target objects W in the storage container 4 are transferred by the transfer robot 31. From the foregoing, the ambient atmosphere of the transfer target objects W stored in the storage container 4 having undergone the purge process changing from the low moisture-concentration state to the high moisture-concentration state in which the concentration is equal to or higher than a predetermined value (for example, the maximum value in the totally open position standby state represented by the chain double-dashed line in FIG. 15) can be prevented from maintaining that high moisture-concentration state.

As described above, with each door opening and closing apparatus 2 according to the present embodiment, the effect of blocking the inner space 4S of the storage container 4 by the lid part 43 held by the door part 22 positioned at the halfway stop position (H) can be attained. Accordingly, with the door opening and closing apparatus 2 according to the present embodiment, the purge concentration in the storage container 4 of a predetermined value or higher can be maintained or secured, without the necessity of using a large amount of the purge-purpose gas (the environmental gas). As a result, with the door opening and closing apparatus 2 according to the present embodiment, an increase in both the purge gas use amount and the costs can be avoided.

In addition, in the door opening and closing apparatus 2 according to the present embodiment, the lid part 43 held by the door part 22 positioned at the halfway stop position (H) does not interfere with the transfer target objects W in the storage container 4 and is not brought into contact with the storage container body 42 in the front-rear direction D. Accordingly, it is possible to prevent or suppress the problems that may arise in the case where the door part 22 is shifted from the totally open position (0) to the totally closed position (C) every time the access operation of the transfer robot 31 to the storage container 4 ends, that is, generation of dust attributed to an increase in the number of shift of the transfer target objects W in the storage container 4 and an increase in the number of contact between the lid part 43 and the storage container body 42.

Further, with the door opening and closing apparatus 2 according to the present embodiment, as the halfway stop position (H), the position where elasticity of the retainers 44 does not act is selected, the retainers 44 being provided at the inner surface 431 of the lid part 43 and capable of elastically holding the edges of the transfer target objects W in the state where the storage inner space 4S of the container body 42 is sealed, that is, in the state where the door part 22 is shifted to the totally closed position (C). Thus, it is also possible to avoid or suppress problems that may arise with the structure where the door part 22 is shifted from the totally open position (O) to the totally closed position (C) every time a transfer target object W is put in or taken out to and from the storage container 4, that is, the risk of generation of dust attributed to an increase in the number of contact between the retainers 44 provided at the inner surface 431 of the lid part 43 and the transfer target object W.

Still further, in each door opening and closing apparatus 2 according to the present embodiment, at and after the time point where the sealed state by the lid part 43 is released on the placing pedestal 23 (the storage container seal releasing process St5), the process of shifting the door part 22 to the totally closed position (C) relative to the storage container 4 (the storage container sealing process St10) is completed basically in one operation (the one operation at and after the time point where the transfer processes of all the transfer target objects W have completed). Accordingly, the number of times of the process of shifting the transfer target objects W in the storage container 4 from the tentative storage position on the shelf part 421 to the normal storage position is just one. Thus, the number of times of the transfer target objects W being shifted on the shelf part 421 can be minimized. This also largely contributes toward avoiding generation of dust, and toward improving yields. As described above, the door opening and closing apparatus 2 according to the present embodiment can prevent or suppress generation of dust, to avoid the risk of a reduction in quality of the transfer target objects W.

Note that, the present invention is not limited to the embodiment described above. For example, in the case where the door part satisfies both the first condition of shifting between the totally closed position and the totally open position while maintaining its attitude and the second condition of shifting frontward and rearward between the totally closed position and the foremost position in the predetermined shifting direction switching region, and shifting upward and downward between the totally open position and the rearmost position in the shifting direction switching region, the halfway stop position of the door part may be set to a predetermined position in a range from the front side than the totally closed position and to the foremost position in the shifting direction switching region (in the embodiment, the shifting direction switching position (P) is the foremost position in the shifting direction switching region). That is, the position identical to the foremost position in the shifting direction switching region can be set as the halfway stop position, and the position of the door part which is on the rear side than the foremost position in the shifting direction switching region and where the rearmost inner surface of the lid part is not on the rear side than the frame foremost surface can be set as the halfway stop position.

Further, the shifting direction switching region where the door part satisfying the first condition and the second condition passes when shifting between the totally closed position and the totally open position may be, in place of being a region that can be represented by one point as in the embodiment, a straight line or a curved line extending in the direction other than the horizontal direction and the vertical direction. When the shifting direction switching region is a region that can be represented by the straight line or the curved line extending in the direction other than the horizontal direction and the vertical direction, one of or a combination of these lines, “the foremost position in the shifting direction switching region” and “the rearmost position in the shifting direction switching region” are positioned as being spaced apart from each other in the front-rear direction and the height direction. Then, the halfway stop position of the door part shifting between the totally closed position and the totally open position via such a shifting direction switching region is just required to be in a range from the front side than the totally closed position and to the foremost position in the shifting direction switching region, and can be set as appropriate.

Further, a predetermined position of the door part where the rearmost inner surface of the lid part is at the position slightly on the rear side than the frame foremost surface can be set as the halfway stop position, or a predetermined position of the door part where the rearmost inner surface of the lid part is at the position identical to the frame foremost surface in the front-rear direction can be set as the halfway stop position. That is, a predetermined position in a range from the position of the door part where the rearmost inner surface of the lid part is at the position identical to the frame foremost surface in the front-rear direction to the position of the door part where the rearmost inner surface of the lid part is on the front side than the frame rearmost surface in the front-rear direction can be set as the halfway stop position.

Further, a predetermined position of the door part where the rearmost inner surface of the lid part is on the rear side (on the back surface side of the storage container) than the frame rearmost surface being nearest to the storage container body in the circumference of the opening in the frame can be set as the halfway stop position. Alternatively, a predetermined position of the door part where the rearmost inner surface of the lid part is at the position identical to the frame rearmost surface in the front-rear direction can be set as the halfway stop position. That is, a predetermined position in a range from the position of the door part where the rearmost inner surface of the lid part is at the position identical to the frame rearmost surface in the front-rear direction to the position of the door part where the rearmost inner surface of the lid part is on the front side than the storage container body foremost surface in the front-rear direction can be set as the halfway stop position. In this case, the rearmost inner surface 43A of the lid part 43 held by the door part 22 put on standby at the halfway stop position (H) is set at the position approaching the inner space 4S of the storage container 4 through the opening 21a formed at the frame 21. Accordingly, as compared to the case where a predetermined position in a range from the position of the door part where the rearmost inner surface of the lid part is at the position identical to the frame foremost surface in the front-rear direction to the position of the door part where the rearmost inner surface of the lid part is on the front side than the frame rearmost surface in the front-rear direction is set as the halfway stop position, the clearance in the front-rear direction between the portion of the storage container body to which the lid part would be closely attached in the sealed state and the lid part held by the door part put on standby at the halfway stop position can be reduced. In the present embodiment employing the frame 21 including a pair of right and left support struts 211 and the frame body 212 supported by the support struts 211, “the frame rearmost surface 21A, which is situated at the circumference of the opening 21a and nearest to the storage container body 42, of the frame 21” refers to the back surface of the frame body 212. That is, the frame rearmost surface 21A can be regarded as the surface, defining the position in the front-rear direction D, of the rearmost opening edge (the opening rear edge) of the opening 21a.

Further, a predetermined position of the door part where the rearmost inner surface of the lid part is at the position slightly on the rear side than the storage container body foremost surface can be set as the halfway stop position. Alternatively, a predetermined position of the door part where the rearmost inner surface of the lid part is at the position identical to the storage container body foremost surface in the front-rear direction can be set as the halfway stop position. That is, a predetermined position of the door part in a range from where the rearmost inner surface of the lid part is at the position identical to the storage container body foremost surface in the front-rear direction to the position of the door part where the rearmost inner surface of the lid part is on the rear side than the storage container body foremost surface in the front-rear direction, and on the front side than the totally closed position can be set as the halfway stop position. In this case, as compared to the case where a predetermined position in a range from the position of the door part where the rearmost inner surface of the lid part is at the position identical to the frame foremost surface in the front-rear direction to the position of the door part where the rearmost inner surface of the lid part is on the front side than the frame rearmost surface in the front-rear direction is set as the halfway stop position, or to the case where a predetermined position in a range from the position of the door part where the rearmost inner surface of the lid part is at the position identical to the frame rearmost surface in the front-rear direction to the position of the door part where the rearmost inner surface of the lid part is on the front side than the storage container body foremost surface in the front-rear direction is set as the halfway stop position, the clearance in the front-rear direction between the portion of the storage container body to which the lid part would be closely attached in the sealed state and the lid part held by the door part put on standby at the halfway stop position can be further reduced.

Here, the storage container body foremost surface being the surface nearest to the frame rearmost surface in the storage container body and the frame rearmost surface are present at an extremely close distance from each other in the front-rear direction. In the state where the storage container body is closely attached to the frame, the boundary portion between the storage container body foremost surface and the frame rearmost surface is extremely small (at the decimal millimeter level). However, from the viewpoint of maintaining the purge concentration in the storage container at a predetermined value or greater, and focusing on the importance of blocking and reducing the frontward opening space of the inner space of the storage container by the lid part every time the transfer process of a transfer target object or a plurality of transfer target objects ends, it can be understood that even such a slight difference influences the operation and effect.

Further, when there is a position of the door part where the retainers 44 are brought into contact with the transfer target objects in the storage container but the elasticity of the retainers 44 does not act, that position of the door part may be set as the halfway stop position.

Further, it is also possible to employ the lid part in which no recessed part is formed at the inner surface, or no retainers are provided.

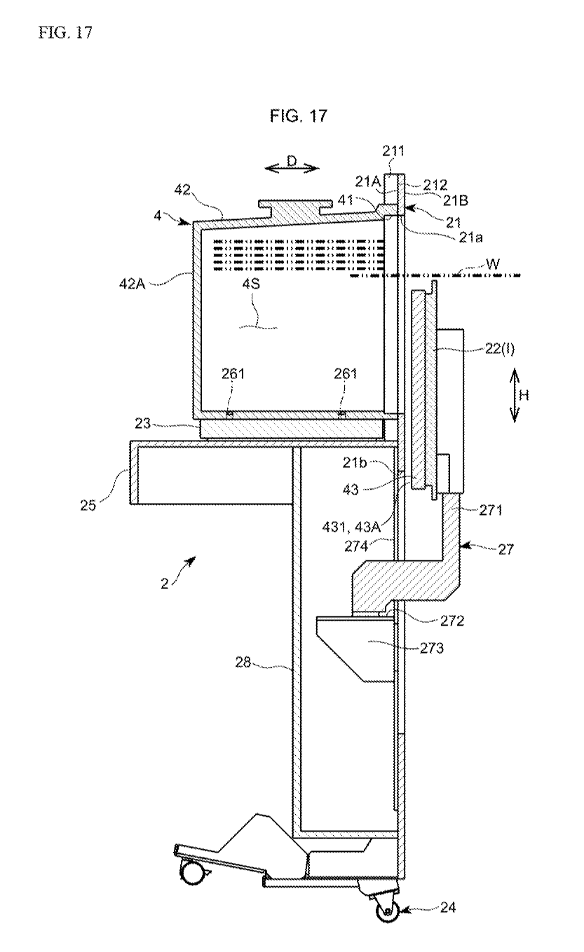

Further, as shown in FIG. 17, the door part 22 may put on standby at the intermediate open position (I) where the storage inner space 4S of the container body 42 is opened by the amount required for an access operation of the transfer robot 31 during the access operation of the transfer robot 31 to the storage container 4. With such a structure, as compared to the structure in which the door part 22 is put on standby at the totally open position (O) during an access operation of the transfer robot 31 to the storage container 4, the opening degree in the height direction of the inner space 4S of the storage container 4 during an access operation of the transfer robot 31 to the storage container 4 can be effectively reduced.

Still further, the mode in which the door part 22 is shifted between the intermediate open position (I) and the halfway stop position (H) is also more advantageous than the mode in which the door part 22 is shifted between the totally open position (O) and the halfway stop position (H) in a reduction in the shift stroke of the door part 22. In the case where the door part 22 is put on standby at the intermediate open position (I) during an access operation of the transfer robot 31 to the storage container 4, the operation flow is similar to that shown in FIGS. 13 and 14 except for the following one point. That is, in place of the door totally open process St9 in FIG. 13, “a door intermediate opening process” is performed, in which the door part 22 is shifted from the halfway stop position (H) to the intermediate open position (I).

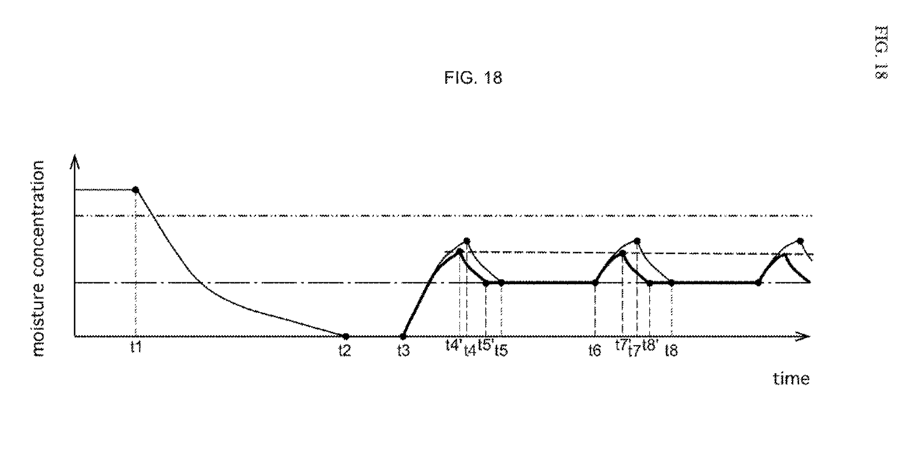

In the case where the door part 22 is put on standby at the intermediate open position (I) during an access operation of the transfer robot 31 to the storage container 4, as can be seen from FIG. 18 showing changes in the moisture concentration in the storage container in association with FIG. 16, at the time point where the inner space 4S of the storage container 4 is opened, the purge concentration in the inner space 4S of the storage container 4 temporarily reduces and the moisture concentration rises. Here, the time required for returning the risen moisture concentration to a low moisture concentration of a predetermined value can be reduced, and the above-described operation and effect can be further improved. FIG. 18 shows, by a relatively bold solid line, changes in the moisture concentration in the storage container in the case where the door part 22 is put on standby at the intermediate open position (I) during an access operation of the transfer robot 31 to the storage container 4.

When the door part 22 is shifted from the totally closed position (C) to the intermediate open position (I) by the storage container seal releasing process St5 immediately before a first access operation of the transfer robot 31 to the storage container 4 having undergone the purge process is started, at and after the time point (the time point where the door part 22 is started to shift from the totally closed position (C) to the intermediate open position (I)) t3, the moisture concentration in the inner space 4S of the storage container 4 rises. However, as compared to the changes in the moisture concentration in the storage container 4 when the door part 22 is shifted from the totally closed position (C) to the totally open position (O) (represented by a relatively fine solid line in FIG. 18), the rising in the moisture concentration in the storage container 4 at and after the time point t3 where the door part 22 is started to shift from the totally closed position (C) to the intermediate open position (I) can be reduced.

Then, by performing the process of positioning the door part 22 at the halfway stop position (H) every time a single access operation of the transfer robot 31 to the storage container 4 ends, and putting the door part 22 on standby at the halfway stop position (H) until immediately before next access operation of the transfer robot 31 to the storage container 4 is performed (the door halfway stop process St7), the rising in the moisture concentration in the inner space 4S of the storage container 4 stops. Here, as described above, the shift stroke of the door part 22 can be reduced by the mode in which the door part 22 is shifted between the intermediate open position (I) and the halfway stop position (H) than the mode in which the door part 22 is shifted between the totally open position (O) and the halfway stop position (H). Accordingly, even when the drive instruction of shifting the door part 22 from the totally open position (O) to the halfway stop position (H) and the drive instruction of shifting the door part 22 from the intermediate open position (I) to the halfway stop position (H) are issued at the identical timing, a time point t4′ where the door part 22 has been shifted from the intermediate open position (I) to the halfway stop position (H) becomes relatively earlier than the time point t4 where the door part 22 has been shifted from the totally open position (O) to the halfway stop position (H).

Further, by performing the door halfway stop process St7 of putting the door part 22 on standby at the halfway stop position (H) from the end of the access operation of the transfer robot 31 to the storage container 4 until immediately before execution of next access operation of the transfer robot 31 to the storage container 4, the moisture concentration in the inner space 4S of the storage container 4 reduces. The time period from the time point t4′ where the door part 22 has been shifted from the intermediate open position (I) to the halfway stop position (H) until a time point t5′ where the moisture concentration in the inner space 4S of the storage container 4 assumes the value identical to the maximum value in the halfway stop position standby state represented by an alternate long and short dashed line in FIGS. 16 and 18 becomes shorter than the time period from the time point t4 where the door part 22 has been shifted from the totally open position (O) to the halfway stop position (H) until the time point t5 where the moisture concentration in the inner space 4S of the storage container 4 assumes the value identical to the maximum value in the halfway stop position standby state. Accordingly, the inside of the storage container 4 can be maintained in an excellent low moisture-concentration state from the time point t5′ where the moisture concentration in the inner space 4S of the storage container 4 assumes the value identical to the maximum value in the halfway stop position standby state to a time point t6′ where the door part 22 is started to shift from the halfway stop position (H) to the intermediate open position (I) for starting next access operation of the transfer robot 31 to the storage container 4.

Further, at the time point t6′ where the door part 22 is started to shift from the halfway stop position (H) to the intermediate open position (I), the moisture concentration of the inner space 4S of the storage container 4 again rises. However, at a time point t7′ where the door part 22 has been shifted from the intermediate open position (I) to the halfway stop position (H), the rising of the moisture concentration in the storage container 4 stops. Based on FIG. 18, it can be seen that the moisture concentration in the storage container 4 at the time point t7′ where the door part 22 has been shifted to the halfway stop position (H) is lower than the moisture concentration in the storage container 4 at the time point t4′ where the door part 22 has been previously shifted to the halfway stop position (H). Further, based on FIG. 18, it can be seen that the time period from the time point t7′ where the door part 22 has been shifted to the halfway stop position (H) to the time point t8′ where the moisture concentration in the inner space 4S of the storage container 4 reduces to the value identical to the maximum value in the halfway stop position standby state becomes shorter than the time period from the time point t4′ where the door part 22 has been shifted to the halfway stop position (H) in the previous access operation of the transfer robot to the storage container to the time point t5′ where the moisture concentration in the inner space 4S of the storage container 4 reduces to the value identical to the maximum value in the halfway stop position standby state.

In this manner, in the case where the door part 22 is put on standby at the intermediate open position (I) during an access operation of the transfer robot 31 to the storage container 4, the maximum value of the moisture concentration in the inner space 4S of the storage container 4 can be set to a lower value than the maximum value of the moisture concentration in the storage container 4 in the case where the door part 22 is put on standby at the totally open state (O) during an access operation of the transfer robot 31 to the storage container 4. Additionally, it becomes possible to reduce the time period required for the temporarily risen moisture concentration in the storage container 4 to return to the value identical to the maximum value in the halfway stop position standby state indicative of an excellent low moisture-concentration state. Accordingly, the time period during which the inner space 4S of the storage container 4 can be maintained in an excellent low moisture-concentration state becomes longer. The changes in the oxygen concentration of the inner space 4S of the storage container 4 are identical or similar to those of the moisture concentration in the inner space 4S of the storage container 4.

Further, the timing of shifting the door part 22 from the intermediate open position (I) to the halfway stop position (H) at and after a time point where a single access operation of the transfer robot 31 to the storage container 4 ends and the transfer process by that access operation ends should be any timing at which the door part 22 or the lid part 43 and the transfer robot 31 do not interfere with each other. That is, at any timing at which the door part 22 or the lid part 43 and the transfer robot 31 do not interfere with each other, the door part 22 may be shifted from the intermediate open position (I) to the halfway stop position (H) immediately after the access operation of the transfer robot 31 to the storage container 4 ends. Further, in the case where the door part 22 or the lid part 43 and the transfer robot 31 interfere with each other if the door part 22 is shifted from the intermediate open position (I) to the halfway stop position (H) immediately after the access operation of the transfer robot 31 to the storage container 4 ends, the door part 22 should be shifted from the intermediate open position (I) to the halfway stop position (H) after a lapse of a predetermined time period from a time point immediately after the access operation of the transfer robot 31 to the storage container 4 ends.

Note that, depending on the setting of the totally open position, the intermediate open position during a putting in or taking out process of the transfer target object stored in the lowermost position in the storage container may become identical or substantially identical to the totally open position.

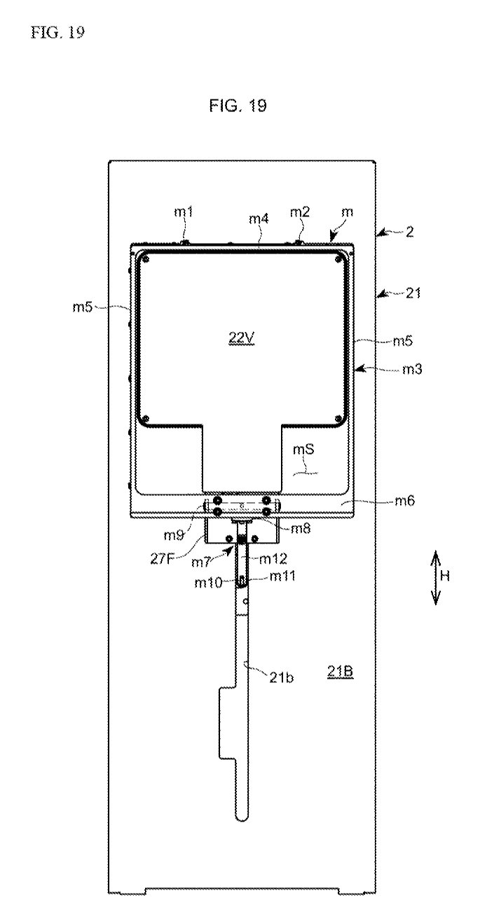

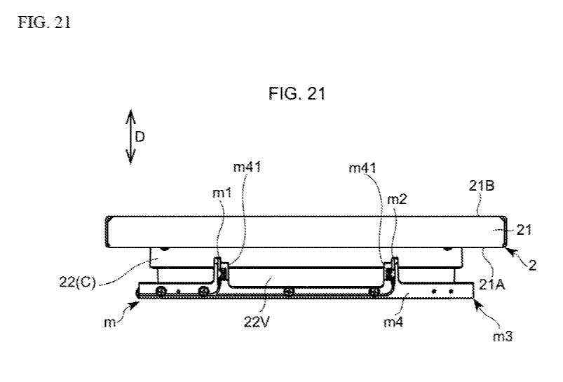

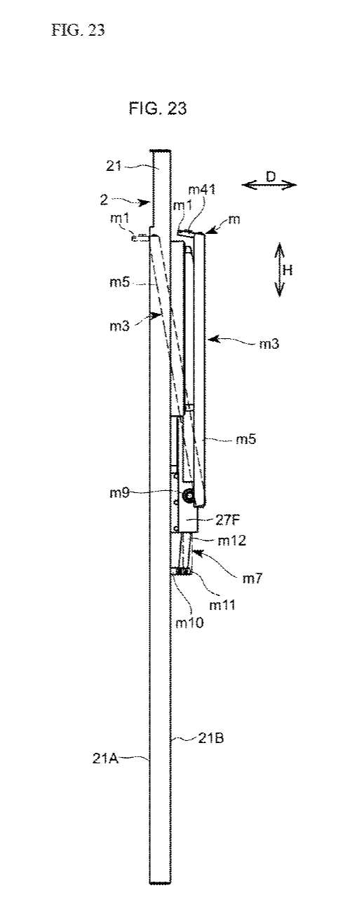

Further, the door opening and closing apparatus may include a mapping unit (transfer target object detecting unit) capable of detecting the presence/absence of the transfer target objects in the storage container or the storage attitude of the transfer target objects. A mapping unit m has, for example as shown in FIGS. 19 to 23, mapping sensors (a transmitter m1, a receiver m2) capable of detecting the presence/absence of the transfer target objects W stored in a multi-stage manner in the height direction H in the storage container 4, and a sensor support part m3 (a sensor frame m3) supporting the mapping sensors m1, m2. The mapping unit m can be set between a mapping retract attitude in which the entire mapping unit m is disposed in the space on the front side than the foremost surface 21B of the frame 21 of the door opening and closing apparatus 2 (the space on the transfer room 3 side in the embodiment) (see FIGS. 19 to 22), and a mapping attitude in which at least the mapping sensors m1, m2 are disposed in the space on the rear side than the rearmost surface 21A of the frame 21 through the opening 21a of the frame 21 (the space on the storage container 4 side in the embodiment) (the attitude represented by phantom lines in FIG. 23). Further, the mapping unit m is capable of shifting in the height direction H while maintaining the mapping retract attitude or the mapping attitude. Then, at least up-down shift of the mapping unit m is integrally performed with the up-down shift of the door part 22. Note that, in FIGS. 19 to 22, part of the components of the door opening and closing apparatus 2 such as the placing pedestal is not shown.

The mapping sensor includes a transmitter m1 (a light emitting sensor) emitting a beam (a light beam) being a signal, and a receiver m2 (a light receiving sensor) that receives the signal issued from the transmitter m1. Note that, the mapping sensor may include the transmitter and a reflecting part for reflecting the light beam emitted from the transmitter toward the transmitter. In this case, the transmitter also has the function of the receiver.

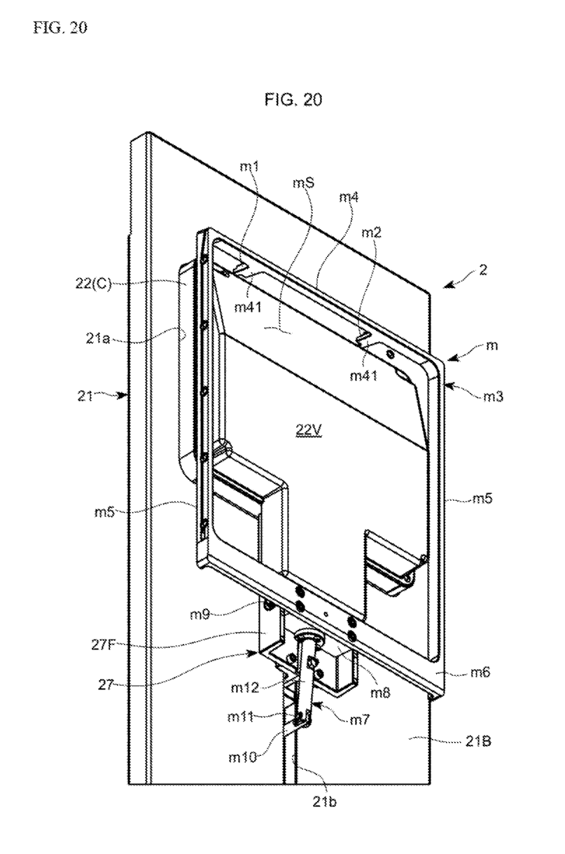

The sensor frame m3 integrally or substantially integrally has an upper frame part m4 to which the mapping sensors m1, m2 are attached, a pair of right and left side frame parts m5 extending downward from the opposite ends of the upper frame part m4, and a lower frame part m6 provided to be suspended between the lower ends of the side frame parts m5. In an inner space m5 of the sensor frame m3 surrounded by the upper frame part m4, the side frame parts m5 and the lower frame part m6 and being open in the front-rear direction D, the door part 22 itself, and a door cover 22V covering the door part 22 and the lid coupling mechanism and the like from the transfer room 3 side are accommodated. At the upper frame part m4, a sensor attaching part m41 to which the mapping sensors m1, m2 are attached is provided so as to project rearward than other portions. Accordingly, the mapping sensors m1, m2 attached to the sensor attaching part m41 of the upper frame part m4 are disposed at the position projecting rearward than the sensor frame m3 except for the sensor attaching part m41 (see FIGS. 20 to 22).

Further, in the present variation, the lower frame part m6 is attached to part of the constituent components of the door shifting mechanism 27. Specifically, the lower frame part m6 is attached to a door support frame 27F (corresponding to the support frame 271 in the embodiment) supporting the door part 22.

Then, in accordance with the up-down actuation of the door part 22 by the door shifting mechanism 27, the lower frame part m6 also integrally actuates. As a result, the entire mapping unit m shifts upward and downward in the direction identical to the door part 22. That is, for example when the door part 22 is shifted downward, the door support frame 27F shifts downward. Thus, the entire sensor frame m3 having the lower frame part m6 attached to the door support frame 27F shifts downward. Accordingly, the entire mapping unit m shifts downward.

In the present embodiment, the lower frame part m6 is attached to the door support frame 27F via part of a tilting mechanism m7 for tilting the entire sensor frame m3 relative to the door support frame 27F.

The tilting mechanism m7 includes a tilting block body m8 fixed to the back surface of the lower frame part m6, and a rotatable tilt shaft m9 disposed in the attitude having its axial direction being the longitudinal direction agreed with the width direction of the door opening and closing apparatus 2, and suspended between the tilting block body m8 and the door support frame 27F. Further, the tilting mechanism m7 includes an advance-retract movable part m10 disposed in the attitude penetrating through the slit-like insert hole 21b formed at the frame 21 in the front-rear direction D and capable of advancing or retracting in the front-rear direction D, and a crank part m12 having its lower end pivotally attached to the front end of the advance-retract movable part m10 via a pivot shaft m11. The upper end of the crank part m12 is fixed to the tilting block body m8. The front end region (the region on the transfer room 3 side) of the tilting block body m8, the tilt shaft m9, and the advance-retract movable part m10, and the crank part m12 are provided on the front side than the foremost surface 21B of the frame 21.

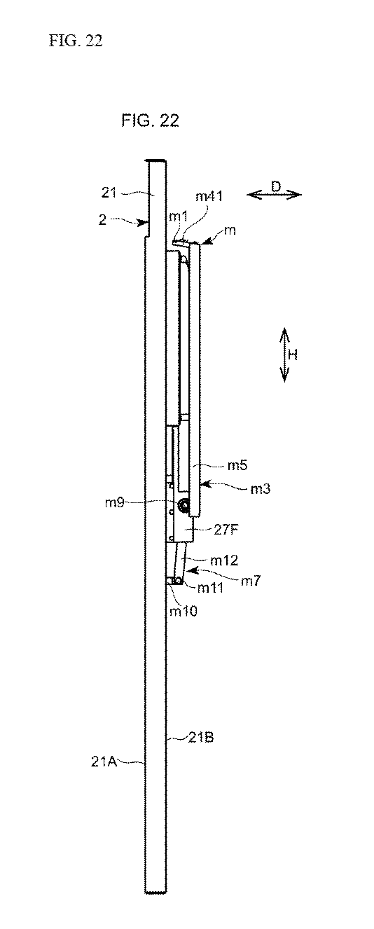

With the tilting mechanism m7 of such a structure, in the state where the mapping unit m is in the mapping retract attitude shown in FIG. 22, by a not-shown drive source shifting the advance-retract movable part m10 frontward (toward the transfer room 3), as shown in FIG. 23, the lower end of the crank part m12 is pushed frontward and the entire crank part m12 is rotated (tilted) about the pivot shaft m11. Thus, the crank part m12 rotates in the direction to shift the upper end rearward (toward the storage container 4), and the tilting block body m8 fixed to the upper end of the crank part m12 is also tilted in the direction identical to the crank part m12 about the tilt shaft m9. Then, the sensor frame m3 having the lower frame part m6 fixed to the tilting block body m8 is tilted in the direction identical to the tilting block body m8. As a result, the upper end region of the side frame parts m5 and the entire upper frame part m4 in the sensor frame m3 project into the space on the front side than the rearmost surface 21A of the frame 21 through the opening 21a (the space on the storage container 4 side). By the foregoing operations, the mapping unit m takes the mapping attitude (see FIG. 23) in which the mapping sensors m1, m2 fixed to the upper frame part m4 are projected into the space on the front side than the rearmost surface 21A of the frame 21 through the opening 21a.

Note that, by the mapping unit m switching the advance-retract movable part m10 rearward (toward the storage container 4) by the drive source, the mapping attitude can be switched to the mapping retract attitude.

Such a mapping process using the mapping unit m is normally performed when the storage container seal releasing process St5 is performed. Specifically, the mapping unit m in the mapping retract attitude until immediately before the storage container seal releasing process St5 is performed is switched to the mapping attitude at the following timing. That is, after the door part 22 is shifted from the totally closed position (C) to the shifting direction switching position (P) (more specifically, to the foremost position in the shifting direction switching region of the present invention), the mapping unit m is switched from the mapping retract attitude to the mapping attitude. Note that, when the mapping unit m is switched from the mapping retract attitude to the mapping attitude in the state where the door part 22 has been shifted to the shifting direction switching position (P), the mapping sensors m1, m2 may interfere with the frame 21. In this case, at the time point where the door part 22 is further lowered by a predetermined distance toward the totally open position (O) after the door part 22 has been shifted to the shifting direction switching position (P), the mapping unit m should be switched from the mapping retract attitude to the mapping attitude. Specifically, the door part 22 is shifted integrally with the mapping unit m in the height direction H such that the mapping sensors m1, m2 of the mapping unit m in the mapping attitude are at the height position slightly higher than the topmost stage of the shelf part 421 (see FIG. 9 and others as to the shelf part 421) in the storage container 4. At the time point where the mapping unit m is switched from the mapping retract attitude to the mapping attitude, the door part 22 has been already shifted from the totally closed position (C) and the opening 21a of the frame 21 and the transfer opening 41 of the storage container 4 are open.

Then, after the mapping unit m is switched from the mapping retract attitude to the mapping attitude, by shifting the door part 22 downward toward the totally open position (O), the mapping unit m also shifts downward while maintaining the mapping attitude. Thus, the control unit 2C performs a mapping process in which the presence/absence or the storage attitude of the transfer target objects W stored in the shelves of the shelf part 421 of the storage container 4 is successively detected using the downwardly shifting mapping sensors m1, m2, from the topmost stage of the shelf part 421 to the lowermost stage of the shelf part 421. That is, the signal route formed between the transmitter m1 and the receiver m2 formed by the transmitter m1 transmitting a signal to the receiver m2 is blocked where the transfer target object W is present, and the signal reaches the receiver m2 without being blocked where the transfer target object W is absent. Thus, the presence/absence or the storage attitude of the transfer target objects W stored juxtaposed with each other in the height direction H in the storage container 4 can be successively detected. Thus, as to the entire shelf part 421 in the storage container 4, information on the presence/absence or the storage attitude of the transfer target objects W can be obtained (transfer target object detecting information). Note that, immediately after the transfer target object detecting information on the transfer target object W placed on the lowermost stage of the shelf part 421 is acquired, the downward shifting of the door part 22 and the mapping unit m at that height position is temporarily stopped, and the mapping unit m is switched from the mapping attitude to the mapping retract attitude. Subsequently, the mapping unit m downwardly shifts together with the door part 22 shifting to the totally open position (O) while maintaining the mapping retract attitude.

Then, based on the transfer target object detecting information acquired by the mapping process, any transfer process of taking out a transfer target object W from a particular stage of the shelf part 421 in the storage container 4, or storing a transfer target object W on a particular stage of the shelf part 421 is performed.

On the other hand, with the door opening and closing apparatus 2 according to the present variation including the mapping unit m capable of shifting upward and downward integrally with the door part 22, the control unit 2C can perform the mapping process using the mapping unit m integrally shifting with the door part 22 also at the timing of shifting the door part 22 from the halfway stop position (H) to the totally open position (O), in addition to the timing at which the storage container seal releasing process St5 is performed. In the present invention, every time a single access operation of the transfer robot to the storage container ends, or a series of access operations ends as will be described later, the door part 22 is shifted from the totally open position (O) to the halfway stop position (H), and the door part 22 is put on standby at the halfway stop position (H) until immediately before next access operation of the transfer robot to the storage container is performed. Then, in the present invention in which the door part 22 is shifted from the halfway stop position (H) to the totally open position (O) immediately before next access operation of the transfer robot to the storage container is performed, the mapping process can be performed at the timing at which the door part 22 is shifted from the halfway stop position (H) to the totally open position (O), that is, immediately before next access operation of the transfer robot to the storage container is performed. With reference to the operation flow of FIG. 13, the mapping process can be performed every time the door totally open process St9 is performed, and the transfer process St6 can be performed based on the transfer target object detecting information obtained by the mapping process.

As described above, the door opening and closing apparatus according to the present variation can perform the mapping process, which would be performed only when the storage container seal releasing process St5 is performed with the well-known door opening and closing apparatus, every time the door totally open process St9 is performed following the door halfway stop process St7. Accordingly, the presence/absence and the storage attitude of the transfer target objects W in the storage container including the transfer target object W transferred by the transfer process St6 immediately before the door halfway stop process St7 is performed can be acquired as the transfer target object detecting information. Thus, for example, it becomes possible to acquire also information on whether a transfer target object W newly put into the storage container or a replaced transfer target object W by the transfer process St6 performed at the time point before the mapping process is placed on a particular stage of the shelf part 421 in a proper attitude. Accordingly, for example when a transfer target object W is stored in the storage container in the tilted attitude lying across stages of the shelf part 421 differing in the height position, it can be grasped that the transfer target object W placed on the stage of the shelf part 421 of a certain height position is in the tilted attitude. In this case, at any appropriate timing after the mapping process and before the transfer process of that transfer target object W, the transfer process of that transfer target object W should be stopped or temporarily stopped, and the transfer target object W in the tilted attitude should be corrected to the proper storage attitude.

Such a door opening and closing apparatus including the mapping unit integrally shifting in the height direction with the door part has the operation and effect described above. Accordingly, even in the case where, before all the transfer processes for one storage container complete, the mapping process is performed at a plurality of time points to find that, for example, a transfer target object put into the storage container in an n-th transfer process St6 (n is an integer greater than 1) in a series of transfer processes is stored in the tilted attitude lying across two stages of the shelf part, the transfer target object detecting information on that transfer target object can be acquired when the door totally open process St9 is performed following the door halfway stop process St7 after the n-th transfer process St6. Thus, for example, an occurrence of the following event can be avoided: the fact that a transfer target object put into the storage container in an n-th transfer process St6 is put on the shelf part in the tilted attitude lying across two stages of the shelf part fails to be recognized; a transfer target object is put into the stage of the shelf part falsely recognized to be open: and the transfer target object is brought into contact with the transfer target object stored in the tilted attitude.

Note that, it is not preferable, in an attempt to increase the number of the mapping process, to shift the mapping unit in the height direction for example by a shifting mechanism other than the door shifting mechanism 27 of the door part 22, because it invites complication not only in the structure but also in control.

Further, it is also possible that the structure shown in FIG. 17, that is, the door opening and closing apparatus in which the door part 22 is put on standby at the intermediate open position (I) during an access operation of the transfer robot 31 to the storage container 4 includes the mapping unit shifting in the height direction integrally with the door part. In this case also, the mapping process by the mapping unit m can be performed not only when the storage container seal releasing process St5 (see FIG. 13) is performed, but every time the door intermediate opening process of shifting the door part 22 from the halfway stop position (H) to the intermediate open position (I) following the door halfway stop process St7 is performed. Since the door intermediate opening process is a process of shifting the door part 22 to the intermediate open position (I) where the storage inner space 4S of the container body 42 is opened just by the amount required for an access operation of the transfer robot 31, at least the presence/absence or the storage attitude of the transfer target object W at a particular stage of the shelf part 421, which is the access destination of the transfer target object W transferred by the transfer process St6 performed following the door intermediate opening process, can be acquired as the transfer target object detecting information.

The mapping unit may be structured as follows. For example, the proximal ends of a pair of sensor arms are rotatably provided at the upper frame part of the sensor frame, as being spaced apart from each other by a predetermined distance in the width direction. In this case, mapping sensors are individually provided at the tips of the sensor arms. By the pair of arms rotating, the attitude can be switched between the mapping retract attitude in which the mapping sensors are disposed in the space on the front side than the foremost surface of the frame (the space on the transfer room side) and the mapping attitude in which the mapping sensors are disposed in the space on the rear side than the rearmost surface of the frame through the opening of the frame (the space on the storage container side). With such a structure, the mechanism of tilting the sensor frame can be dispensed with. Then, according to the process procedure similar to the process procedure with the mapping unit m, the mapping process can be performed at the timing before the transfer process St6 (see FIG. 13) is performed. Accordingly, by performing the mapping processes at a plurality of time points before all the transfer processes for one storage container ends, it becomes possible to prevent an occurrence of a problem that the transfer target objects are brought into contact with each other during a transfer process.

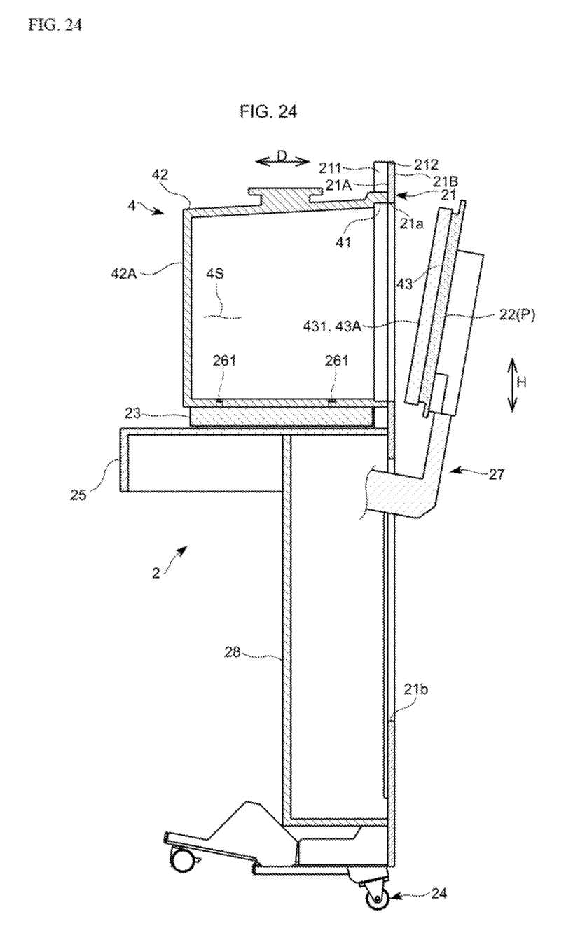

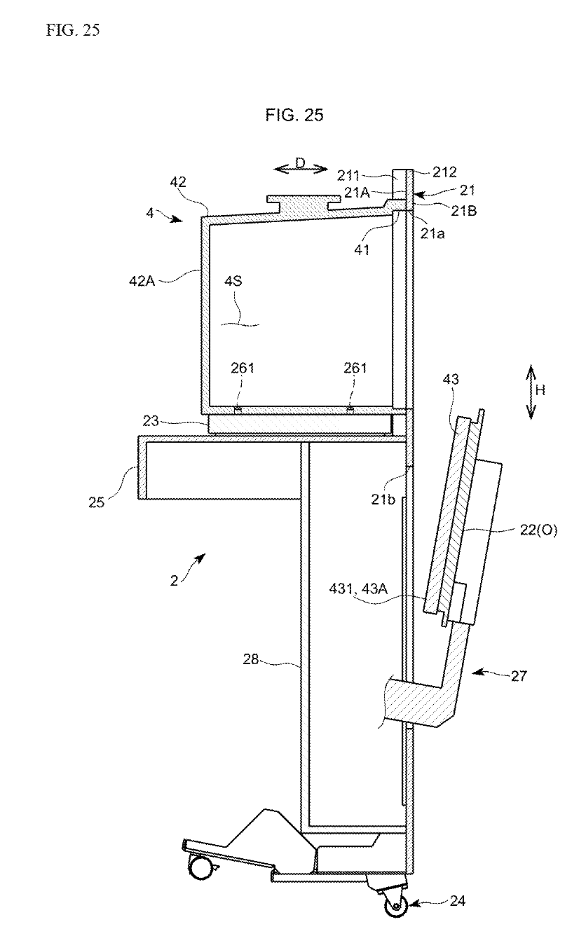

The door part may perform a rotation operation during the entire or part of shifting between the totally closed position and the totally open position. For example, as shown in FIGS. 24 and 25, the door part 22 may be set to linearly shift between the shifting direction switching position (P) and the totally open position (O), while being set to rotationally shift between the totally closed position (C) and the shifting direction switching position (P). In this case, the attitude of the door part 22 positioned at the shifting direction switching position (P) shown in FIG. 24 is tilted by a predetermined angle, and the door part 22 shifts between the shifting direction switching position (P) and the totally open position (O) shown in FIG. 25 while maintaining the tilted attitude. In this case, a predetermined position of the door part on the front side than the totally closed position and where the rearmost inner surface of the lid part is at the position on the rear side than the frame foremost surface can be set as “the halfway stop position of the door part”. The attitude of the door part positioned at the halfway stop position may be an attitude tilted by a predetermined angle, or may be an upright attitude as in the embodiment described above. In the case where the attitude of the door part positioned at the halfway stop position is the attitude tilted by a predetermined angle, the halfway stop position is not particularly limited so long as it is the position of the door part on the front side than the totally closed position and where at least part of the rearmost inner surface of the lid part held by the door part in the tilted attitude is at a position on the rear side than the frame foremost surface. Note that, it is also possible to set, as the halfway stop position, a predetermined position of the door part on the front side than the totally closed position and where the entire rearmost inner surface of the lid part held by the door part in the tilted attitude is at a position on the rear side than the frame foremost surface.

Note that, the specific structure and the drive source of the door shifting mechanism 27 which are not partially shown in FIGS. 24 and 25 can also be changed as appropriate.

As has been described above, the door opening and closing apparatus of the present invention can structure part of the EFEM, and is applicable also to other transfer apparatus other than the EFEM.

Further, the door opening and closing apparatus of the present invention can be used for structuring part of a sorter apparatus in which, for example, a plurality of the door opening and closing apparatuses of the present invention are disposed along the wall surface of the transfer room, and transfer target objects can be exchanged, by a transfer robot disposed in the transfer room, between the storage containers individually placed on the placing pedestals of the door opening and closing apparatuses. Alternatively, the sorter apparatus may be any of a sorter apparatus in which a plurality of door opening and closing apparatuses are disposed along a common wall surface of the transfer room, a sorter apparatus in which one or a plurality of door opening and closing apparatuses are disposed at different wall surfaces of the transfer room (for example, opposite wall surfaces such as the front wall and the rear wall), and a sorter apparatus in which a buffer station or an aligner is disposed at any of the side surfaces, and the transfer target objects can be exchanged, put in or taken out by the transfer robot among the storage containers individually placed on the placing pedestals of the door opening and closing apparatuses, or between the storage container and the buffer station or the aligner.

The transfer room adjacent to which the door opening and closing apparatuses of the present invention is disposed includes the transfer robot in its inner space. In the present invention, the wafer transferring process to and from the storage container on the placing pedestal of each of the door opening and closing apparatuses may be performed by a single transfer robot, or a plurality of the transfer robots.

The door opening and closing apparatus disposed on the wall surface of the transfer room may be one in number.

In the embodiment described above, wafers are exemplarily shown as the transfer target objects. However, the transfer target objects may be reticles, liquid crystal transfer target objects, glass transfer target objects, culture plates, culture vessels, dishes, or petri dishes. That is, the present invention is applicable to the transfer technique of any transfer target objects stored in a container in various fields such as semiconductors, liquid crystals, cell cultivations and the like.

Further, the door opening and closing apparatus of the present invention is not limited to a load port, and can be used as the interface portion between the storage container and the transfer room.

Still further, it is also possible to form an airflow curtain flowing from an upper point toward a lower point near the opening of the frame in the inner space of the transfer room, and when at least the door part is at the totally open position, the gas atmosphere in the transfer room is prevented or suppressed by the airflow curtain from entering the storage container. Note that, when the door part is at the halfway stop position, the rearmost inner surface of the lid part is positioned on the rear side than the frame rearmost surface. Accordingly, it is expected that the lid part can prevent or suppress the gas atmosphere in the transfer room from entering the storage container, and therefore the process of forming the airflow curtain may be temporarily stopped. This makes it possible to reduce also the use amount of gas for forming the airflow curtain. It goes without saying that the present invention does not exclude the structure of continuously forming the airflow curtain irrespective of the position of the door part.

The transfer robot may be a transfer robot having three or more transfer target object gripping parts (the hands in the embodiment). Further, it may be a transfer robot having one transfer target object gripping part. Still further, it may be a transfer robot whose transfer target object gripping parts include predetermined components or the like other than the hands.

Further, the transfer robot is just required to be disposed in the transfer room. The door opening and closing apparatus may include the transfer robot.

In order to shorten the time period during which the entire inner space of the storage container is opened to the transfer room side, it is preferable to put the door part on standby at the predetermined halfway stop position every time a single access operation of the transfer robot to the storage container ends and until immediately before next access operation of the transfer robot to the storage container is performed. However, with the door opening and closing apparatus of the present invention, it is also possible to put the door part on standby at the predetermined halfway stop position every time a series of access operations of the transfer robot to the storage container ends and until immediately before next access operation of the transfer robot to the storage container is performed. In this case also, as compared to the structure in which the door part is kept on standby at the totally open position from the start of the transfer process of the transfer target objects in the storage container until the transfer processes of all the transfer target objects end, that is, until all the access operations of the transfer robot to the storage container end, the time period during which the entire inner space of the storage container is totally opened to the transfer room side can be shortened. Note that, in the case where the door part is put on standby at the predetermined halfway stop position every time a series of access operations of the transfer robot to the storage container ends and until immediately before next access operation of the transfer robot to the storage container is performed, it is on condition that the term “a series of” in “every time a series of access operations of the transfer robot ends” refers to the number smaller than the number of access operations of the transfer robot required for completing all the transfer processes of the transfer target objects in the storage container.

Note that, the timing at which the door part is shifted to the predetermined halfway stop position and put on standby may be selectable as appropriate from “every time a single access operation of the transfer robot ends” and “every time a series of access operations of the transfer robot ends”. In this case, for example the timing at which the door part is shifted to the predetermined halfway stop position and put on standby may be switchable between “every time a single access operation of the transfer robot ends” and “every time a series of access operations of the transfer robot ends” based on an instruction from the control unit of the door opening and closing apparatus or the control unit of a higher-level apparatus (the EFEM 1 or the processing apparatus M in the embodiment), or a unique identification code attached to the storage container (for example the code recorded on an RFID tag).

Furthermore, with the door opening and closing apparatus of the present invention, in addition to the timing at which the door part is shifted to the predetermined halfway stop position and put on standby being selectable as appropriate from “every time a single access operation of the transfer robot ends” and “every time a series of access operations of the transfer robot ends”, the mode in which the door part is shifted to the totally closed position after the last access operation of the transfer robot to the transfer target objects in the storage container ends without shifting the door part to the predetermined halfway stop position (a normal mode) may also be selectable.

Further, the door opening and closing apparatus of the present invention is not limited to a load port, and can be used as the interface portion between the storage container and the transfer room.

As the purge process in the storage container, in addition to the bottom purge process, it is also possible to employ a so-called front purge process, in which an environmental gas is supplied from the front side of the inner space of the storage container in the state where the inner space of the storage container is opened frontward (toward the transfer room). A front purge part with which the front purge process is executed may be provided at the storage container body, the lid body, or the door opening and closing apparatus.

The genre or type of the storage container, the specific structure or functions of the transfer room can be also changed as appropriate. As the environmental gas required for performing the purge process, any gas other than nitrogen gas and dry air may be employed.

The embodiment exemplarily shows the mode in which the door opening and closing apparatus 2 includes the control unit 2C, and the control unit 2C controls the actuation of the constituent members such as shifting of the door part 22. In this case, for example, the timing at which the door part is shifted from the totally open position or the intermediate open position to the halfway stop position may be the time point where the door opening and closing apparatus receives a door closing instruction.

Alternatively, it is also possible to employ the mode in which a control unit (a control unit 3C of the entire EFEM or a control unit MC of the processing apparatus M being the higher-level controllers) that controls the actuation of a higher-level apparatus than the door opening and closing apparatus (the EFEM or the processing apparatus in the embodiment) also controls the actuation of the door opening and closing apparatus. In this case, for example, the timing at which the door part is shifted from the totally open position or the intermediate open position to the halfway stop position may be the time point where the higher-level controller issues a door closing instruction.

Further, the control unit is not limited to the dedicated system, and can be realized by a normal computer system. For example, by installing, from a recording medium (a flexible disc, a CD-ROM and the like) storing a program for executing the above-described process, the program in a general-purpose computer, the control unit executing the process can be structured. Any means for supplying such a program can be employed. In addition to supplying via a predetermined recording medium as described above, for example the program may be supplied via a communication line, a communication network, a communication system and the like. In this case, for example, the program may be posted on a bulletin board system (BBS) of a communication network, and the program may be provided as being superimposed on carrier wave via the network. Then, by activating the program supplied in this manner and executing the program similarly to other application programs under control of OS, the above-described process can be executed.

In addition, the specific structure of the constituent members is not limited to those in the embodiment, and various modifications can be made within the scope not deviating from the spirit of the present invention.

What is claimed is:

1. A door opening and closing apparatus comprising:
a plate-like frame that structures part of a wall surface of a transfer room and is provided with an opening for opening the transfer room;
a door part capable of opening and closing the opening; and
a placing pedestal on which a storage container having a storage container body and a lid part capable of opening and closing an inner space of the storage container body can be placed such that the lid part faces the door part,
wherein the door part opens and closes when a transfer target object is transferred by a transfer robot disposed in the transfer room between the storage container and the transfer room, the door part opening and closing while shifting between a totally closed position where the inner space of the storage container body is sealed at least by the lid part held by the door part and a totally open position where the inner space of the storage container body is totally opened frontward,
in a direction along which the storage container placed on the placing pedestal and the frame are aligned with each other, a side where the frame is positioned is referred to as a front side and a side where the storage container is positioned is referred to as a rear side,
the lid part has an inner surface facing the inner space of the storage container body, the inner surface having a rearmost inner surface being nearest to a back surface of the storage container body,
the frame has a frame foremost surface which is situated at a circumference of the opening and farthest from the storage container body, and
every time a single access operation or a series of access operations of the transfer robot to the storage container subjected to a purge process with an environmental gas ends and until immediately before next access operation of the transfer robot to the storage container is performed, the door part becomes on standby at a predetermined halfway stop position on the front side than the totally closed position and where the rearmost inner surface of the lid part is on the rear side than the frame foremost surface of the frame.

2. A door opening and closing apparatus comprising:
a plate-like frame that structures part of a wall surface of a transfer room and is provided with an opening for opening the transfer room;
a door part capable of opening and closing the opening; and
a placing pedestal on which a storage container having a storage container body and a lid part capable of opening and closing an inner space of the storage container body can be placed such that the lid part faces the door part,
wherein the door part opens and closes when a transfer target object is transferred by a transfer robot disposed in the transfer room between the storage container and the transfer room, the door part opening and closing while shifting between a totally closed position where the inner space of the storage container body is sealed at least by the lid part held by the door part and a totally open position where the inner space of the storage container body is totally opened frontward, the door part maintaining an attitude thereof while shifting,
in a direction along which the storage container placed on the placing pedestal and the frame are aligned with each other, a side where the frame is positioned is referred to as a front side and a side where the storage container is positioned is referred to as a rear side,
the door part shifts frontward and rearward between the totally closed position and a foremost position in a predetermined shifting direction switching region, and shifts upward and downward between the totally open position and a rearmost position in the shifting direction switching region, and
every time a single access operation or a series of access operations of the transfer robot to the storage container subjected to a purge process with an environmental gas ends and until immediately before next access operation of the transfer robot to the storage container is performed, the door part becomes on standby at a predetermined halfway stop position on the front side than the totally closed position and before the foremost position in the shifting direction switching region.

3. The door opening and closing apparatus according to claim 1, wherein
the frame has a frame rearmost surface which is situated at the circumference of the opening and nearest to the storage container body, and
the halfway stop position is a predetermined position on the front side than the totally closed position and where the rearmost inner surface of the lid part is on the rear side than the frame rearmost surface of the frame.

4. The door opening and closing apparatus according to claim 1, wherein
the frame has a frame rearmost surface which is situated at the circumference of the opening and nearest to the storage container body,
the storage container body has a storage container body foremost surface being nearest to the frame rearmost surface, and
the halfway stop position is a predetermined position on the front side than the totally closed position and where the rearmost inner surface of the lid body is on the rear side than the storage container body foremost surface.

5. The door opening and closing apparatus according to claim 1, further comprising a retainer provided at the inner surface of the lid part and capable of elastically holding an edge of the transfer target object in a state where the inner space of the storage container body is sealed,
wherein the halfway stop position is a position where elasticity of the retainer does not act.

6. The door opening and closing apparatus according to claim 1, wherein
during the access operation of the transfer robot to the storage container, the door part is on standby at an intermediate open position where the inner space of the storage container body is opened in a height direction by an amount necessary for the access operation of the transfer robot.
